(19) United States
(12) Patent Application Publication
(10) Pub. No.: US 2020/0325327 A1
(43) Pub. Date: Oct. 15, 2020

(54) CURED-FILM-FORMING COMPOSITION, ORIENTATION MATERIAL, AND RETARDATION MATERIAL

(71) Applicant: NISSAN CHEMICAL CORPORATION, Tokyo (JP)

(72) Inventors: Jun ITO, Funabashi-shi (JP); Naoya NISHIMURA, Funabashi-shi (JP)

(73) Assignee: NISSAN CHEMICAL CORPORATION, Tokyo (JP)

(21) Appl. No.: 16/756,631

(22) PCT Filed: Oct. 16, 2018
(86) PCT No.: PCT/JP2018/038483

§ 371 Date: Apr. 16, 2020

(30) Foreign Application Priority Data
Oct. 16, 2017 (JP) 2017-200249

(51) Int. Cl. C08L 67/02; C08J 5/18; C09K 19/56; G02B 1/111; G02F 1/1337; G02B 5/30; H01L 51/52

(52) U.S. Cl. CPC C08L 67/02; C08J 5/18; C09K 19/56; G02B 1/111; C08J 2433/14; G02B 5/3083; H01L 51/5281; C08L 2203/16; C08J 2367/02; G02F 1/133711

(57) ABSTRACT

A cured-film-forming composition for forming a cured-film, an orientation material and a retardation material, includes: a component (A), which is a cinnamic acid derivative of the following Formula (1):

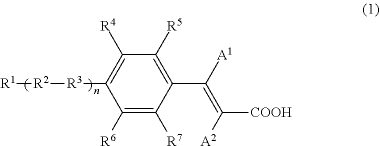

(wherein A¹ and A² are each independently a hydrogen atom or methyl group; R¹ is a hydrogen atom, etc., R² is an aromatic group, etc., R³ is a single bond, an oxygen atom, etc., R⁴ to R⁷ are each independently a hydrogen atom, etc., and n is an integer of 0 to 3); a component (B), which is a hydrophilic polymer having one or more substituents selected from a hydroxy group, a carboxyl group, and an amino group; a component (C), which is a crosslinking agent; and further including a component (D), which is a crosslinking catalyst as needed.

### TECHNICAL FIELD

The present invention relates to a liquid crystal orientation agent for photo-orientation to orient liquid crystal molecules, an orientation material, and a retardation material. More particularly, the present invention relates to a liquid crystal orientation agent for photo-orientation useful in producing a patterned retardation material used in a 3D display for circular polarization glasses or a retardation material used in a circular polarization plate used as an anti-reflective coating of an organic EL display, an orientation material, and a retardation material.

### BACKGROUND ART

In a 3D display for circular polarization glasses, a retardation material is generally disposed on a display element for forming an image, such as a liquid crystal panel. The retardation material has two types of retardation regions having different retardation characteristics, wherein each type includes a plurality of regularly arranged regions; i.e., the retardation material is patterned. As used herein, the term “patterned retardation material” refers to a retardation material patterned so as to have a plurality of retardation regions having different retardation characteristics.

The patterned retardation material can be produced by optical patterning of a retardation material composed of polymerizable liquid crystals as disclosed in, for example, Patent Document 1. The optical patterning of the retardation material composed of polymerizable liquid crystals involves the use of a photo-orientation technique known for formation of an orientation material for a liquid crystal panel. Specifically, a coating film formed of a photo-orientation material is disposed on a substrate, and the coating film is irradiated with two types of polarized light having different polarization directions, to thereby form a photo-orientation film as an orientation material including two types of liquid crystal orientation regions having different directions of liquid crystal orientation control. A retardation material in the form of a solution containing polymerizable liquid crystals is applied onto the photo-orientation film to thereby achieve the orientation of the polymerizable liquid crystals. Thereafter, the oriented polymerizable liquid crystals are cured to form a patterned retardation material.

An anti-reflective coating of an organic EL display is composed of a linear polarization plate and a ¼ wavelength retardation plate. Light incident on the surface of an image display panel is converted into linearly polarized light by the linear polarization plate, and then converted into circularly polarized light by the ¼ wavelength retardation plate. Although the circularly polarized incident light is reflected on, for example, the surface of the image display panel, the rotation direction of the polarization plane is inverted during this reflection. Consequently, unlike the case of the incident light, the reflected light is converted into linearly polarized light by the ¼ wavelength retardation plate in a direction shielded by the linear polarization plate, and then the converted light is shielded by the linear polarization plate. Thus, emission of the light to the outside is considerably reduced.

Regarding such a ¼ wavelength retardation plate, Patent Document 2 proposes a method for producing a ¼ wavelength retardation plate by combining a ½ wavelength plate and a ¼ wavelength plate so that the resultant optical film exhibits reverse dispersion property. This method can produce an optical film having reverse dispersion property by using a liquid crystal material having positive dispersion property in a wide wavelength region used for display of a color image.

In recent years, there has been proposed a liquid crystal material having reverse dispersion property that can be applied to such a retardation layer (Patent Documents 3 and 4). The use of such a liquid crystal material having reverse dispersion property enables production of a single-layer retardation plate having reverse dispersion property, rather than production of a ¼ wavelength retardation plate by combination of two retardation layers; i.e., a ½ wavelength plate and a ¼ wavelength plate. Thus, the material enables production of an optical film having a simple structure and capable of securing a desired retardation in a wide wavelength region.

An orientation layer is used for orienting liquid crystals. The orientation layer is formed by any known method, such as the rubbing method or the photo-orientation method. The photo-orientation method is useful since it does not cause occurrence of static electricity or dust (i.e., a problem involved in the rubbing method) and enables quantitative orientation control.

Known photo-orientation materials available for formation of an orientation material by the photo-orientation method include an acrylic resin or polyimide resin having in its side chain photodimerizable moieties, such as a cinnamoyl group and a chalcone group. Such a resin has been reported to exhibit a property of controlling liquid crystal orientation (hereinafter may be referred to as “liquid crystal orientation property”) through polarized UV irradiation (see Patent Documents 5 to 7).

In accordance with a recent demand for a reduction in the weight and thickness of a device, a retardation material has been required to have a smaller thickness. This requirement leads to the use of a method for producing a thinner retardation material by peeling of an orientation film (which has a role in orienting polymerizable liquid crystals on the orientation film) after curing of the polymerizable liquid crystals. Thus, the orientation layer is required to be easily peelable after curing of the polymerizable liquid crystals.

Also, the orientation layer is required to have solvent resistance besides liquid crystal orientation ability and peelability. For example, the orientation layer may be exposed to heat or a solvent during a production process for a retardation material. Exposure of the orientation layer to a solvent may cause significant deterioration of the liquid crystal orientation ability.

In view of achievement of stable liquid crystal orientation ability, for example, Patent Document 8 proposes a liquid crystal orientation agent containing a polymer component having a photo-crosslinkable structure and a thermally crosslinkable structure, and a liquid crystal orientation agent containing a polymer component having a photo-crosslinkable structure and a compound having a thermally crosslinkable structure.

### PRIOR ART DOCUMENTS

### Patent Documents

Patent Document 1: Japanese Unexamined Patent Application Publication No. 2005-49865 (JP 2005-49865 A)

Patent Document 2: Japanese Unexamined Patent Application Publication No. 10-68816 (JP 10-68816 A)

Patent Document 3: U.S. Pat. No. 8,119,026 Specification

Patent Document 4: Japanese Unexamined Patent Application Publication No. 2009-179563 (JP 2009-179563 A)

Patent Document 5: Japanese Patent No. 3611342

Patent Document 6: Japanese Unexamined Patent Application Publication No. 2009-058584 (JP 2009-058584 A)

Patent Document 7: Japanese Unexamined Patent Application Publication (Translation of PCT Application) No. 2001-517719 (JP 2001-517719 A)

Patent Document 8: Japanese Patent No. 4207430

### SUMMARY OF THE INVENTION

### Problems to be Solved by the Invention

The present invention has been accomplished on the basis of the aforementioned findings and study results. Accordingly, an object of the present invention is to provide a cured-film-forming composition for providing an orientation material that has excellent photoreaction efficiency and solvent resistance, can orient polymerizable liquid crystals at high sensitivity, and can be peeled from a layer of the polymerizable liquid crystals after curing of the polymerizable liquid crystals.

Other objects and advantages of the present invention will become apparent from the following description.

### Means for Solving the Problems

A first aspect of the present invention is a cured-film-forming composition characterized by comprising:

a component (A), which is a cinnamic acid derivative of the following Formula (1):

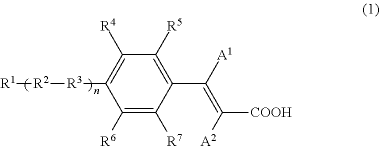

(wherein A and A² are each independently a hydrogen atom or methyl group; R¹ is a substituent selected from a hydrogen atom, a halogen atom, a C₁₋₆ alkyl, a C₁₋₆ haloalkyl, a C₁₋₆ alkoxy, a C₁₋₆ haloalkoxy, a C₃₋₈ cycloalkyl, a C₃₋₈ halocycloalkyl, a C₂₋₆ alkenyl, a C₂₋₆ haloalkenyl, a C₃₋₈ cycloalkenyl, a C₃₋₈ halocycloalkenyl, a C₂₋₆ alkynyl, a C₂₋₆ haloalkynyl, a (C₁₋₆ alkyl)carbonyl, a (C₁₋₆ haloalkyl)carbonyl, a (C₁₋₆ alkoxy)carbonyl, a (C₁₋₆ haloalkoxy)carbonyl, a (C₁₋₆ alkylamino)carbonyl, a (C₁₋₆ haloalkyl)aminocarbonyl, a di(C₁₋₆ alkyl)aminocarbonyl, cyano, and nitro; R² is a divalent aromatic group, a divalent alicyclic group, a divalent heterocyclic group, or a divalent fused-ring group; R³ is a single bond, an oxygen atom, —COO—, or —OCO—; R⁴ to R⁷ are each independently a substituent selected from a hydrogen atom, a halogen atom, a C₁₋₆ alkyl group, a C₁₋₆ haloalkyl group, a C₁₋₆ alkoxy group, a C₁₋₆ haloalkoxy group, a cyano group, and a nitro group; and n is an integer of 0 to 3);

a component (B), which is a hydrophilic polymer having one or more substituents selected from a hydroxy group, a carboxyl group, and an amino group; and

a component (C), which is a crosslinking agent.

In the first aspect of the present invention, the component (B) is preferably at least one polymer selected from the group consisting of polyether polyol, polyester polyol, polycarbonate polyol, and polycaprolactone polyol.

In the first aspect of the present invention, the component (B) is preferably cellulose or a derivative thereof.

In the first aspect of the present invention, the component (B) is preferably an acrylic polymer having at least one of a polyethylene glycol ester group and a C₂₋₅ hydroxyalkyl ester group, and at least one of a carboxyl group and a phenolic hydroxy group.

In the first aspect of the present invention, the component (B) is preferably an acrylic copolymer prepared by polymerization reaction of monomers containing at least one of a monomer having a polyethylene glycol ester group and a monomer having a C₂₋₅ hydroxyalkyl ester group, and at least one of a monomer having a carboxyl group and a monomer having a phenolic hydroxy group.

In the first aspect of the present invention, the component (B) is preferably an acrylic polymer having in its side chain a hydroxyalkyl group.

In the first aspect of the present invention, the component (C) is preferably a polymer prepared by polymerization of a monomer containing an N-hydroxymethyl compound or an N-alkoxymethyl(meth)acrylamide compound.

In the first aspect of the present invention, the composition preferably further comprises a crosslinking catalyst as a component (D).

In the first aspect of the present invention, the mass ratio of the component (A) to the component (B) is preferably 5:95 to 60:40.

In the first aspect of the present invention, the amount of the component (C) is preferably 10 parts by mass to 500 parts by mass relative to 100 parts by mass of the total amount of the component (A) and the component (B).

In the first aspect of the present invention, the amount of the component (D) is preferably 0.01 parts by mass to 10 parts by mass relative to 100 parts by mass of the total amount of the compound as the component (A) and the polymer as the component (B).

A second aspect of the present invention is an orientation material characterized by being produced from the cured-film-forming composition according to the first aspect of the present invention.

A third aspect of the present invention is a retardation material characterized by being formed by using a cured film produced from the cured-film-forming composition according to the first aspect of the present invention.

### Effects of the Invention

According to the present invention, there is provided a cured-film-forming composition for providing an orientation material that has excellent photoreaction efficiency and solvent resistance, can orient polymerizable liquid crystals at high sensitivity, and can be peeled from a layer of the polymerizable liquid crystals after curing of the polymerizable liquid crystals.

### MODES FOR CARRYING OUT THE INVENTION

<Cured-Film-Forming Composition>

The cured-film-forming composition of the present embodiment contains a component (A), which is a low-molecular-weight photo-orientation component; a component (B), which is a hydrophilic polymer; and a component (C), which is a crosslinking agent. The cured-film-forming composition of the present embodiment may further contain a crosslinking catalyst as a component (D) besides the component (A), the component (B), and the component (C). The composition may contain an additional additive, so long as the effects of the present invention are not impaired.

The respective components will next be described in detail.

<Component (A)>

The component (A) contained in the cured-film-forming composition of the present invention is a cinnamic acid derivative of Formula (1).

Examples of the halogen atom in Formula (1) include fluorine atom, chlorine atom, bromine atom, and iodine atom. The “halo” as used herein also refers to such a halogen atom.

The “C_{a-b} alkyl” in Formula (1) is a linear or branched hydrocarbon group having a carbon atom number of a to b. Specific examples of the C_{a-b} alkyl include methyl group, ethyl group, n-propyl group, i-propyl group, n-butyl group, i-butyl group, s-butyl group, t-butyl group, n-pentyl group, 1-methylbutyl group, 2-methylbutyl group, 3-methylbutyl group, 1-ethylpropyl group, 1,1-dimethylpropyl group, 1,2-dimethylpropyl group, 2,2-dimethylpropyl group, n-hexyl group, 1-methylpentyl group, 2-methylpentyl group, 1,1-dimethylbutyl group, 1,3-dimethylbutyl group, heptyl group, octyl group, nonyl group, decyl group, undecyl group, and dodecyl group. Each C_{a-b} alkyl is selected so that the number of carbon atoms thereof falls within a specified range.

The “C_{a-b} haloalkyl” in Formula (1) is a linear or branched hydrocarbon group having a carbon atom number of a to b wherein a hydrogen atom bonded to a carbon atom is optionally substituted with a halogen atom. In the case of substitution with two or more halogen atoms, the halogen atoms may be identical to or different from one another. Specific examples of the C_{a-b} haloalkyl include fluoromethyl group, chloromethyl group, bromomethyl group, iodomethyl group, difluoromethyl group, chlorofluoromethyl group, dichloromethyl group, bromofluoromethyl group, trifluoromethyl group, chlorodifluoromethyl group, dichlorofluoromethyl group, trichloromethyl group, bromodifluoromethyl group, bromochlorofluoromethyl group, dibromofluoromethyl group, 2-fluoroethyl group, 2-chloroethyl group, 2-bromoethyl group, 2,2-difluoroethyl group, 2-chloro-2-fluoroethyl group, 2,2-dichloroethyl group, 2-bromo-2-fluoroethyl group, 2,2,2-trifluoroethyl group, 2-chloro-2,2-difluoroethyl group, 2,2-dichloro-2-fluoroethyl group, 2,2,2-trichloroethyl group, 2-bromo-2,2-difluoroethyl group, 2-bromo-2-chloro-2-fluoroethyl group, 2-bromo-2,2-dichloroethyl group, 1,1,2,2-tetrafluoroethyl group, pentafluoroethyl group, 1-chloro-1,2,2,2-tetrafluoroethyl group, 2-chloro-1,1,2,2-tetrafluoroethyl group, 1,2-dichloro-1,2,2-trifluoroethyl group, 2-bromo-1,1,2,2-tetrafluoroethyl group, 2-fluoropropyl group, 2-chloropropyl group, 2-bromopropyl group, 2-chloro-2-fluoropropyl group, 2,3-dichloropropyl group, 2-bromo-3-fluoropropyl group, 3-bromo-2-chloropropyl group, 2,3-dibromopropyl group, 3,3,3-trifluoropropyl group, 3-bromo-3,3-difluoropropyl group, 2,2,3,3-tetrafluoropropyl group, 2-chloro-3,3,3-trifluoropropyl group, 2,2,3,3,3-pentafluoropropyl group, 1,1,2,3,3,3-hexafluoropropyl group, heptafluoropropyl group, 2,3-dichloro-1,1,2,3,3-pentafluoropropyl group, 2-fluoro-1-methylethyl group, 2-chloro-1-methylethyl group, 2-bromo-1-methylethyl group, 2,2,2-trifluoro-1-(trifluoromethyl)ethyl group, 1,2,2,2-tetrafluoro-1-(trifluoromethyl)ethyl group, 2,2,3,3,4,4-hexafluorobutyl group, 2,2,3,4,4,4-hexafluorobutyl group, 2,2,3,3,4,4,4-heptafluorobutyl group, 1,1,2,2,3,3,4,4-octafluorobutyl group, nonafluorobutyl group, 4-chloro-1,1,2,2,3,3,4,4-octafluorobutyl group, 2-fluoro-2-methylpropyl group, 2-chloro-1,1-dimethylethyl group, 2-bromo-1,1-dimethylethyl group, 5-chloro-2,2,3,4,4,5,5-heptafluoropentyl group, and tridecafluorohexyl group. Each C_{a-b} haloalkyl is selected so that the number of carbon atoms thereof falls within a specified range.

The “C_{a-b} cycloalkyl” in Formula (1) is a cyclic hydrocarbon group having a carbon atom number of a to b wherein a 3- to 6-membered monocyclic or polycyclic structure can be formed. Each ring may be optionally substituted with an alkyl group having a carbon atom number falling within a specified range. Specific examples of the C_{a-b} cycloalkyl include cyclopropyl group, 1-methylcyclopropyl group, 2-methylcyclopropyl group, 2,2-dimethylcyclopropyl group, 2,2,3,3-tetramethylcyclopropyl group, cyclobutyl group, cyclopentyl group, 2-methylcyclopentyl group, 3-methylcyclopentyl group, cyclohexyl group, 2-methylcyclohexyl group, 3-methylcyclohexyl group, 4-methylcyclohexyl group, and bicyclo[2.2.1]heptan-2-yl group. Each C_{a-b} cycloalkyl is selected so that the number of carbon atoms thereof falls within a specified range.

The “C_{a-b} halocycloalkyl” in Formula (1) is a cyclic hydrocarbon group having a carbon atom number of a to b wherein a hydrogen atom bonded to a carbon atom is optionally substituted with a halogen atom and a 3- to 6-membered monocyclic or polycyclic structure can be formed. Each ring may be optionally substituted with an alkyl group having a carbon atom number falling within a specified range. The substitution with a halogen atom may be at a ring structure moiety, at a side chain moiety, or at both of these moieties. In the case of substitution with two or more halogen atoms, the halogen atoms may be identical to or different from one another. Specific examples of the C_{a-b} halocycloalkyl include 2,2-difluorocyclopropyl group, 2,2-dichlorocyclopropyl group, 2,2-dibromocyclopropyl group, 2,2-difluoro-1-methylcyclopropyl group, 2,2-dichloro-1-methylcyclopropyl group, 2,2-dibromo-1-methylcyclopropyl group, 2,2,3,3-tetrafluorocyclobutyl group, 2-(trifluoromethyl)cyclohexyl group, 3-(trifluoromethyl)cyclohexyl group, and 4-(trifluoromethyl)cyclohexyl group. Each C_{a-b} halocycloalkyl is selected so that the number of carbon atoms thereof falls within a specified range.

The “C_{a-b} alkenyl” in Formula (1) is a linear or branched unsaturated hydrocarbon group having a carbon atom number of a to b and having one or more double bonds in the molecule. Specific examples of the C_{a-b} alkenyl include vinyl group, 1-propenyl group, 2-propenyl group, 1-methylethenyl group, 2-butenyl group, 1-methyl-2-propenyl group, 2-methyl-2-propenyl group, 2-pentenyl group, 2-methyl-2-butenyl group, 3-methyl-2-butenyl group, 2-ethyl-2-propenyl group, 1,1-dimethyl-2-propenyl group, 2-hexenyl group, 2-methyl-2-pentenyl group, 2,4-dimethyl-2,6-heptadienyl group, and 3,7-dimethyl-2,6-octadienyl group. Each C_{a-b} alkenyl is selected so that the number of carbon atoms thereof falls within a specified range.

The “C_{a-b} haloalkenyl” in Formula (1) is a linear or branched unsaturated hydrocarbon group having a carbon atom number of a to b and having one or more double bonds in the molecule wherein a hydrogen atom bonded to a carbon atom is optionally substituted with a halogen atom. In the case of substitution with two or more halogen atoms, the halogen atoms may be identical to or different from one another. Specific examples of the C_{a-b} haloalkenyl include 2,2-dichlorovinyl group, 2-fluoro-2-propenyl group, 2-chloro-2-propenyl group, 3-chloro-2-propenyl group, 2-bromo-2-propenyl group, 3-bromo-2-propenyl group, 3,3-difluoro-2-propenyl group, 2,3-dichloro-2-propenyl group, 3,3-dichloro-2-propenyl group, 2,3-dibromo-2-propenyl group, 2,3,3-trifluoro-2-propenyl group, 2,3,3-trichloro-2-propenyl group, 1-(trifluoromethyl)ethenyl group, 3-chloro-2-butenyl group, 3-bromo-2-butenyl group, 4,4-difluoro-3-butenyl group, 3,4,4-trifluoro-3-butenyl group, 3-chloro-4,4,4-trifluoro-2-butenyl group, and 3-bromo-2-methyl-2-propenyl group. Each C_{a-b} haloalkenyl is selected so that the number of carbon atoms thereof falls within a specified range.

The “C_{a-b} cycloalkenyl” in Formula (1) is a cyclic unsaturated hydrocarbon group having a carbon atom number of a to b and having one or more double bonds wherein a 3- to 6-membered monocyclic or polycyclic structure can be formed. Each ring may be optionally substituted with an alkyl group having a carbon atom number falling within a specified range. The double bond(s) may be in an endo- or exo-form. Specific examples of the C_{a-b} cycloalkenyl include 2-cyclopenten-1-yl group, 3-cyclopenten-1-yl group, 2-cyclohexen-1-yl group, 3-cyclohexen-1-yl group, and bicyclo[2.2.1]-5-hepten-2-yl group. Each C_{a-b} cycloalkenyl is selected so that the number of carbon atoms thereof falls within a specified range.

The “C_{a-b} halocycloalkenyl” in Formula (1) is a cyclic unsaturated hydrocarbon group having a carbon atom number of a to b and having one or more double bonds wherein a hydrogen atom bonded to a carbon atom is optionally substituted with a halogen atom, and a 3- to 6-membered monocyclic or polycyclic structure can be formed. Each ring may be optionally substituted with an alkyl group having a carbon atom number falling within a specified range. The double bond(s) may be in an endo- or exo-form. The substitution with a halogen atom may be at a ring structure moiety, at a side chain moiety, or at both of these moieties. In the case of substitution with two or more halogen atoms, the halogen atoms may be identical to or different from one another. Specific examples of the C_{a-b} halocycloalkenyl include 2-chlorobicyclo[2.2.1]-5-hepten-2-yl group. Each C_{a-b} halocycloalkenyl is selected so that the number of carbon atoms thereof falls within a specified range.

The “C_{a-b} alkynyl” in Formula (1) is a linear or branched unsaturated hydrocarbon group having a carbon atom number of a to b and having one or more triple bonds in the molecule. Specific examples of the C_{a-b} alkynyl include ethynyl group, 1-propynyl group, 2-propynyl group, 2-butynyl group, 1-methyl-2-propynyl group, 2-pentynyl group, 1-methyl-2-butynyl group, 1,1-dimethyl-2-propynyl group, and 2-hexynyl group. Each C_{a-b} alkynyl is selected so that the number of carbon atoms thereof falls within a specified range.

The “C_{a-b} haloalkynyl” in Formula (1) is a linear or branched unsaturated hydrocarbon group having a carbon atom number of a to b and having one or more triple bonds in the molecule wherein a hydrogen atom bonded to a carbon atom is optionally substituted with a halogen atom. In the case of substitution with two or more halogen atoms, the halogen atoms may be identical to or different from one another. Specific examples of the C_{a-b} haloalkynyl include 2-chloroethynyl group, 2-bromoethynyl group, 2-iodoethynyl group, 3-chloro-2-propynyl group, 3-bromo-2-propynyl group, and 3-iodo-2-propynyl group. Each C_{a-b} haloalkynyl is selected so that the number of carbon atoms thereof falls within a specified range.

The “C_{a-b} alkoxy” in Formula (1) is an alkyl-O— group wherein the alkyl has a carbon atom number of a to b and has the meaning as defined above. Specific examples of the C_{a-b} alkoxy include methoxy group, ethoxy group, n-propyloxy group, i-propyloxy group, n-butyloxy group, i-butyloxy group, s-butyloxy group, t-butyloxy group, n-pentyloxy group, and n-hexyloxy group. Each C_{a-b} alkoxy is selected so that the number of carbon atoms thereof falls within a specified range.

The “C_{a-b} haloalkoxy” in Formula (1) is a haloalkyl-O— group wherein the haloalkyl has a carbon atom number of a to b and has the meaning as defined above. Specific examples of the C_{a-b} haloalkoxy include difluoromethoxy group, trifluoromethoxy group, chlorodifluoromethoxy group, bromodifluoromethoxy group, 2-fluoroethoxy group, 2-chloroethoxy group, 2,2,2-trifluoroethoxy group, 1,1,2,2-tetrafluoroethoxy group, 2-chloro-1,1,2-trifluoroethoxy group, 2-bromo-1,1,2-trifluoroethoxy group, pentafluoroethoxy group, 2,2-dichloro-1,1,2-trifluoroethoxy group, 2,2,2-trichloro-1,1-difluoroethoxy group, 2-bromo-1,1,2,2-tetrafluoroethoxy group, 2,2,3,3-tetrafluoropropyloxy group, 1,1,2,3,3,3-hexafluoropropyloxy group, 2,2,2-trifluoro-1-(trifluoromethyl)ethoxy group, heptafluoropropyloxy group, and 2-bromo-1,1,2,3,3,3-hexafluoropropyloxy group. Each C_{a-b} haloalkoxy is selected so that the number of carbon atoms thereof falls within a specified range.

The “(C_{a-b} alkyl)carbonyl” in Formula (1) is an alkyl-C(O)— group wherein the alkyl has a carbon atom number of a to b and has the meaning as defined above. Specific examples of the (C_{a-b} alkyl)carbonyl include acetyl group, propionyl group, butyryl group, isobutyryl group, valeryl group, isovaleryl group, 2-methylbutanoyl group, pivaloyl group, hexanoyl group, and heptanoyl group. Each (C_{a-b} alkyl)carbonyl is selected so that the number of carbon atoms thereof falls within a specified range.

The “(C_{a-b} haloalkyl)carbonyl” in Formula (1) is a haloalkyl-C(O)— group wherein the haloalkyl has a carbon atom number of a to b and has the meaning as defined above. Specific examples of the (C_{a-b} haloalkyl)carbonyl include fluoroacetyl group, chloroacetyl group, difluoroacetyl group, dichloroacetyl group, trifluoroacetyl group, chlorodifluoroacetyl group, bromodifluoroacetyl group, trichloroacetyl group, pentafluoropropionyl group, heptafluorobutanoyl group, and 3-chloro-2,2-dimethylpropanoyl group. Each (C_{a-b} haloalkyl)carbonyl is selected so that the number of carbon atoms thereof falls within a specified range.

The “(C_{a-b} alkoxy)carbonyl” in Formula (1) is an alkyl-O—C(O)— group wherein the alkyl has a carbon atom number of a to b and has the meaning as defined above. Specific examples of the (C_{a-b} alkoxy)carbonyl include methoxycarbonyl group, ethoxycarbonyl group, n-propyloxycarbonyl group, i-propyloxycarbonyl group, n-butoxycarbonyl group, i-butoxycarbonyl group, and t-butoxycarbonyl group. Each (C_{a-b} alkoxy)carbonyl is selected so that the number of carbon atoms thereof falls within a specified range.

The “(C_{a-b} haloalkoxy)carbonyl” in Formula (1) is a haloalkyl-O—C(O)— group wherein the haloalkyl has a carbon atom number of a to b and has the meaning as defined above. Specific examples of the (C_{a-b} haloalkoxy)carbonyl include 2-chloroethoxycarbonyl group, 2,2-difluoroethoxycarbonyl group, 2,2,2-trifluoroethoxycarbonyl group, and 2,2,2-trichloroethoxycarbonyl group. Each (C_{a-b} haloalkoxy)carbonyl is selected so that the number of carbon atoms thereof falls within a specified range.

The “(C_{a-b} alkylamino)carbonyl” in Formula (1) is a carbamoyl group wherein one hydrogen atom is substituted with an alkyl group having a carbon atom number of a to b and having the meaning as defined above. Specific examples of the (C_{a-b} alkylamino)carbonyl include methylcarbamoyl group, ethylcarbamoyl group, n-propylcarbamoyl group, i-propylcarbamoyl group, n-butylcarbamoyl group, i-butylcarbamoyl group, s-butylcarbamoyl group, and t-butylcarbamoyl group. Each (C_{a-b} alkylamino)carbonyl is selected so that the number of carbon atoms thereof falls within a specified range.

The “(C_{a-b} haloalkyl)aminocarbonyl” in Formula (1) is a carbamoyl group wherein one hydrogen atom is substituted with a haloalkyl group having a carbon atom number of a to b and having the meaning as defined above. Specific examples of the (C_{a-b} haloalkyl)aminocarbonyl include 2-fluoroethylcarbamoyl group, 2-chloroethylcarbamoyl group, 2,2-difluoroethylcarbamoyl group, and 2,2,2-trifluoroethylcarbamoyl group. Each (C_{a-b} haloalkyl)aminocarbonyl is selected so that the number of carbon atoms thereof falls within a specified range.

The “di(C_{a-b} alkyl)aminocarbonyl” in Formula (1) is a carbamoyl group wherein both hydrogen atoms are substituted with alkyl groups that may be identical to or different from each other, wherein each alkyl group has a carbon atom number of a to b and has the meaning as defined above. Specific examples of the di(C_{a-b} alkyl)aminocarbonyl include N,N-dimethylcarbamoyl group, N-ethyl-N-methylcarbamoyl group, N,N-diethylcarbamoyl group, N,N-di-n-propylcarbamoyl group, and N,N-di-n-butylcarbamoyl group. Each di(C_{a-b} alkyl)aminocarbonyl is selected so that the number of carbon atoms thereof falls within a specified range.

Particularly preferably, the substituents R¹, R², R³, R⁴, and R⁵ of the cinnamic acid derivative of Formula (1) are each independently a substituent selected from a hydrogen atom, a halogen atom, a C₁₋₆ alkyl, a C₁₋₆ haloalkyl, a C₁₋₆ alkoxy, a C₁₋₆ haloalkoxy, cyano, and nitro.

From the viewpoint of orientation sensitivity, R³ is preferably a substituent selected from those defined above (other than a hydrogen atom), more preferably a substituent selected from a halogen atom, a C₁₋₆ alkyl, a C₁₋₆ haloalkyl, a C₁₋₆ alkoxy, a C₁₋₆ haloalkoxy, cyano, and nitro.

Examples of the divalent aromatic group of R² include 1,4-phenylene group, 2-fluoro-1,4-phenylene group, 3-fluoro-1,4-phenylene group, and 2,3,5,6-tetrafluoro-1,4-phenylene group; examples of the divalent heterocyclic group of R² include 1,4-pyridylene group, 2,5-pyridylene group, and 1,4-furanylene group; and examples of the divalent fused-ring group of R² include 2,6-naphthylene group. R² is preferably a 1,4-phenylene group.

Preferred examples of the compound of Formula (1) include compounds of the following Formulae (1-1) to (1-5):

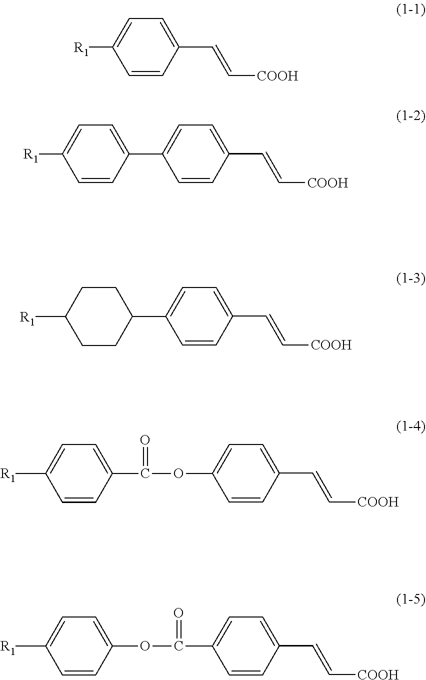

(wherein R¹ has the same meaning as defined above in Formula (1)).

The compound of Formula (1) can be synthesized by any appropriate combination of generally used organic chemical techniques.

The compound as the component (A) of the cured-film-forming composition of the present embodiment may be a mixture of a plurality of compounds of Formula (1).

<Component (B)>

The component (B) contained in the cured-film-forming composition of the present embodiment is a hydrophilic polymer.

The polymer as the component (B) may be a polymer having one or more substituents selected from a hydroxy group, a carboxyl group, and an amino group (hereinafter the polymer may be referred to as “specific polymer”).

In the cured-film-forming composition of the present embodiment, the specific polymer selected as the component (B) is preferably a highly hydrophilic polymer having hydrophilicity higher than that of the component (A). The specific polymer is preferably a polymer having a hydrophilic group such as a hydroxy group, a carboxyl group, or an amino group; specifically, a polymer having one or more substituents selected from a hydroxy group, a carboxyl group, and an amino group.

Examples of the polymer as the component (B) include polymers having a linear-chain structure or a branched-chain structure, such as acrylic polymer, polyamic acid, polyimide, polyvinyl alcohol, polyester, polyester polycarboxylic acid, polyether polyol, polyester polyol, polycarbonate polyol, polycaprolactone polyol, polyalkyleneimine, polyallylamine, celluloses (cellulose or derivatives thereof), phenol novolac resin, and melamine formaldehyde resin; and cyclic polymers, such as cyclodextrins.

Of these, the acrylic polymer may be a polymer prepared by polymerization of a monomer having an unsaturated double bond, such as an acrylic acid ester, a methacrylic acid ester, or styrene.

The specific polymer as the component (B) is preferably a hydroxyalkylcyclodextrin, cellulose, an acrylic polymer having at least one of a polyethylene glycol ester group and a C₂₋₅ hydroxyalkyl ester group and at least one of a carboxyl group and a phenolic hydroxy group, an acrylic polymer having in its side chain an aminoalkyl group, an acrylic polymer having in its side chain a hydroxyalkyl group (e.g., polyhydroxyethyl methacrylate), polyether polyol, polyester polyol, polycarbonate polyol, and polycaprolactone polyol.

No particular limitation is imposed on, for example, the main chain skeleton and side chain type of an acrylic polymer having at least one of a polyethylene glycol ester group and a C₂₋₅ hydroxyalkyl ester group and at least one of a carboxyl group and a phenolic hydroxy group (i.e., a preferred example of the specific polymer as the component (B)), so long as the acrylic polymer has the aforementioned structure.

A preferred structural unit having at least one of a polyethylene glycol ester group and a C₂₋₅ hydroxyalkyl ester group is represented by the following Formula [B1].

A preferred structural unit having at least one of a carboxyl group and a phenolic hydroxy group is represented by the following Formula [B2].

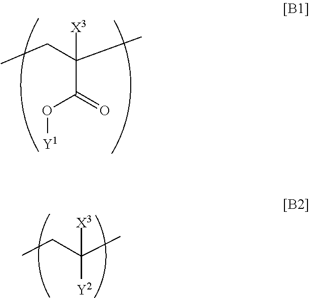

In Formulae [B1] and [B2], X³ and X⁴ are each independently a hydrogen atom or methyl group; Y¹ is a H—(OCH₂CH₂)ₙ— group (wherein n is 2 to 50, preferably 2 to 10) or a C₂₋₅ hydroxyalkyl group; and Y² is a carboxyl group or a phenolic hydroxy group.

The acrylic polymer (i.e., an example of the component (B)) has a weight average molecular weight of preferably 3,000 to 200,000, more preferably 4,000 to 150,000, still more preferably 5,000 to 100,000. An excessively high weight average molecular weight of more than 200,000 may cause a reduction in solubility in a solvent, resulting in poor handling property, whereas an excessively low weight average molecular weight of less than 3,000 may cause insufficient curing during a thermal curing process, resulting in poor solvent resistance and thermal resistance. The weight average molecular weight is determined by gel permeation chromatography (GPC) using polystyrene as a standard sample. The same shall apply hereinafter.

The acrylic polymer (i.e., an example of the component (B)) is readily synthesized by a method involving copolymerization of a monomer having at least one of a polyethylene glycol ester group and a C₂₋₅ hydroxyalkyl ester group (hereinafter the monomer may be referred to as “monomer b1”) and a monomer having at least one of a carboxyl group and a phenolic hydroxy group (hereinafter the monomer may be referred to as “monomer b2”).

Examples of the aforementioned monomer having a polyethylene glycol ester group include monoacrylate or monomethacrylate of H—(OCH₂CH₂)ₙ—OH (wherein n is 2 to 50, preferably 2 to 10).

Examples of the aforementioned monomer having a C₂₋₅ hydroxyalkyl ester group include 2-hydroxyethyl methacrylate, 2-hydroxyethyl acrylate, 2-hydroxypropyl methacrylate, 2-hydroxypropyl acrylate, 4-hydroxybutyl acrylate, and 4-hydroxybutyl methacrylate.

Examples of the aforementioned monomer having a carboxyl group include acrylic acid, methacrylic acid, and vinylbenzoic acid.

Examples of the aforementioned monomer having a phenolic hydroxy group include p-hydroxystyrene, m-hydroxystyrene, and o-hydroxystyrene.

In the present embodiment, the acrylic polymer (i.e., an example of the component (B)) may be synthesized by using an additional monomer other than the monomer b1 and the monomer b2 (specifically, a monomer having neither a hydroxy group nor a carboxyl group) in combination with the monomers b1 and b2, so long as the effects of the present invention are not impaired.

Examples of the additional monomer include acrylic acid ester compounds, such as methyl acrylate, ethyl acrylate, propyl acrylate, isopropyl acrylate, butyl methacrylate, butyl acrylate, isobutyl acrylate, and t-butyl acrylate; methacrylic acid ester compounds, such as methyl methacrylate, ethyl methacrylate, propyl methacrylate, isopropyl methacrylate, isobutyl methacrylate, and t-butyl methacrylate; maleimide compounds, such as maleimide, N-methylmaleimide, N-phenylmaleimide, and N-cyclohexylmaleimide; acrylamide compounds; acrylonitrile; maleic anhydride; styrene compounds; and vinyl compounds.

The amounts of the monomer b1 and the monomer b2 used for preparation of the acrylic polymer (i.e., an example of the component (B)) are preferably 2% by mole to 95% by mole and 5% by mole to 98% by mole, respectively, relative to the total amount of all monomers used for preparation of the acrylic polymer as the component (B).

When the monomer b2 is a monomer having only a carboxyl group, the amounts of the monomer b1 and the monomer b2 are preferably 60% by mole to 95% by mole and 5% by mole to 40% by mole, respectively, relative to the total amount of all monomers used for preparation of the acrylic polymer as the component (B).

When the monomer b2 is a monomer having only a phenolic hydroxy group, the amounts of the monomer b1 and the monomer b2 are preferably 2% by mole to 80% by mole and 20% by mole to 98% by mole, respectively. When the amount of the monomer b2 is excessively small, the liquid crystal orientation property is likely to be unsatisfactory, whereas when the amount of the monomer b2 is excessively large, the compatibility of the component (B) with the component (A) is likely to be reduced.

No particular limitation is imposed on the method for preparing the acrylic polymer (i.e., an example of the component (B)). For example, the acrylic polymer is prepared by polymerization reaction in a solvent containing the monomer b1, the monomer b2, an optional monomer other than the monomers b1 and b2, and, for example, a polymerization initiator at a temperature of 50° C. to 110° C. In this case, no particular limitation is imposed on the solvent used for the polymerization reaction, so long as the solvent dissolves the monomer b1, the monomer b2, the optional monomer other than the monomers b1 and b2, and, for example, the polymerization initiator. Specific examples of the solvent are described below in the section <Solvent>.

Examples of the acrylic polymer having in its side chain an aminoalkyl group (i.e., a preferred example of the specific polymer as the component (B)) include polymers prepared by polymerization of any of aminoalkyl ester monomers, such as aminoethyl acrylate, aminoethyl methacrylate, aminopropyl acrylate, and aminopropyl methacrylate; and polymers prepared by copolymerization of such an aminoalkyl ester monomer and one or more monomers selected from the group consisting of the monomer b1, the monomer b2, and a monomer other than the monomers b1 and b2 (e.g., a monomer having neither a hydroxy group nor a carboxy group).

Examples of the acrylic polymer having in its side chain a hydroxyalkyl group (i.e., a preferred example of the specific polymer as the component (B)) include polymers prepared by polymerization of any of hydroxyalkyl ester monomers, such as hydroxyethyl acrylate, hydroxyethyl methacrylate, hydroxypropyl acrylate, hydroxypropyl methacrylate, hydroxybutyl acrylate, hydroxybutyl methacrylate, hydroxypentyl acrylate, and hydroxypentyl methacrylate; and polymers prepared by copolymerization of such a hydroxyalkyl ester monomer and one or more monomers selected from the group consisting of the monomer b1, the monomer b2, and a monomer other than the monomers b1 and b2 (e.g., a monomer having neither a hydroxy group nor a carboxy group).

The acrylic polymer (i.e., an example of the component (B)) prepared by the aforementioned method is generally in the form of a solution of the polymer in a solvent.

A solution of the acrylic polymer (i.e., an example of the component (B)) prepared by the aforementioned method is added to, for example, diethyl ether or water with stirring for reprecipitation. The resultant precipitate is filtered and washed, and then dried at ambient temperature or dried with heating at ambient pressure or under reduced pressure, to thereby prepare powder of the acrylic polymer as an example of the component (B). The polymerization initiator and unreacted monomer coexistent with the acrylic polymer (i.e., an example of the component (B)) can be removed by the aforementioned operation, to thereby yield powder of the purified acrylic polymer as an example of the component (B). In the case where the acrylic polymer cannot be sufficiently purified by a single operation, the resultant powder may be redissolved in a solvent, followed by repetition of the aforementioned operation.

Examples of the polyether polyol (i.e., a preferred example of the specific polymer as the component (B)) include polyethylene glycol, polypropylene glycol, propylene glycol, and products prepared by addition or condensation of, for example, propylene oxide, polyethylene glycol, or polypropylene glycol to a polyhydric alcohol such as bisphenol A, triethylene glycol, or sorbitol. Specific examples of the polyether polyol include ADEKA polyether P-series, G-series, EDP-series, BPX-series, FC-series, and CM-series available from ADEKA Corporation; and UNIOX (registered trademark) HC-40, HC-60, ST-30E, ST-40E, G-450, and G-750, UNIOL (registered trademark) TG-330, TG-1000, TG-3000, TG-4000, HS-1600D, DA-400, DA-700, and DB-400, and NONION (registered trademark) LT-221, ST-221, and OT-221 available from NOF Corporation.

Examples of the polyester polyol (i.e., a preferred example of the specific polymer as the component (B)) include products prepared by reaction of a polycarboxylic acid such as adipic acid, sebacic acid, or isophthalic acid with a diol such as ethylene glycol, propylene glycol, butylene glycol, polyethylene glycol, or polypropylene glycol. Specific examples of the polyester polyol include POLYLITE (registered trademark) OD-X-286, OD-X-102, OD-X-355, OD-X-2330, OD-X-240, OD-X-668, OD-X-2108, OD-X-2376, OD-X-2044, OD-X-688, OD-X-2068, OD-X-2547, OD-X-2420, OD-X-2523, OD-X-2555, and OD-X-2560 available from by DIC Corporation; and Polyol P-510, P-1010, P-2010, P-3010, P-4010, P-5010, P-6010, F-510, F-1010, F-2010, F-3010, P-1011, P-2011, P-2013, P-2030, N-2010, and PNNA-2016 available from Kuraray Co., Ltd.

Examples of the polycaprolactone polyol (i.e., a preferred example of the specific polymer as the component (B)) include products prepared by ring-opening polymerization of 8-caprolactam in the presence of a polyhydric alcohol such as trimethylolpropane or ethylene glycol as an initiator. Specific examples of the polycaprolactone polyol include POLYLITE (registered trademark) OD-X-2155, OD-X-640, and OD-X-2568 available from DIC Corporation; and PLACCEL (registered trademark) 205, L205AL, 205U, 208, 210, 212, L212AL, 220, 230, 240, 303, 305, 308, 312, 320, and 410 available from Daicel Corporation.

Examples of the polycarbonate polyol (i.e., a preferred example of the specific polymer as the component (B)) include products prepared by reaction of a polyhydric alcohol such as trimethylolpropane or ethylene glycol with, for example, diethyl carbonate, diphenyl carbonate, or ethylene carbonate. Specific examples of the polycarbonate polyol include PLACCEL (registered trademark) CD205, CD205PL, CD210, CD220, C-590, C-1050, C-2050, C-2090, and C-3090 available from Daicel Corporation.

Examples of the cellulose (i.e., a preferred example of the specific polymer as the component (B)) include hydroxyalkyl celluloses, such as hydroxyethyl cellulose and hydroxypropyl cellulose; hydroxyalkyl alkyl celluloses, such as hydroxyethyl methyl cellulose, hydroxypropyl methyl cellulose, and hydroxyethyl ethyl cellulose; and celluloses. For example, hydroxyalkyl celluloses such as hydroxyethyl cellulose and hydroxypropyl cellulose are preferred.

Examples of the cyclodextrin (i.e., a preferred example of the specific polymer as the component (B)) include cyclodextrins, such as α-cyclodextrin, β-cyclodextrin, and γ-cyclodextrin; methylated cyclodextrins, such as methyl-α-cyclodextrin, methyl-β-cyclodextrin, and methyl-γ-cyclodextrin; and hydroxyalkyl cyclodextrins, such as hydroxymethyl-α-cyclodextrin, hydroxymethyl-β-cyclodextrin, hydroxymethyl-γ-cyclodextrin, 2-hydroxyethyl-α-cyclodextrin, 2-hydroxyethyl-β-cyclodextrin, 2-hydroxyethyl-γ-cyclodextrin, 2-hydroxypropyl-α-cyclodextrin, 2-hydroxypropyl-β-cyclodextrin, 2-hydroxypropyl-γ-cyclodextrin, 3-hydroxypropyl-α-cyclodextrin, 3-hydroxypropyl-β-cyclodextrin, 3-hydroxypropyl-γ-cyclodextrin, 2,3-dihydroxypropyl-α-cyclodextrin, 2,3-dihydroxypropyl-β-cyclodextrin, and 2,3-dihydroxypropyl-γ-cyclodextrin.

The melamine formaldehyde resin (i.e., a preferred example of the specific polymer as the component (B)) is a resin prepared by polycondensation between melamine and formaldehyde; specifically, a resin of the following formula.

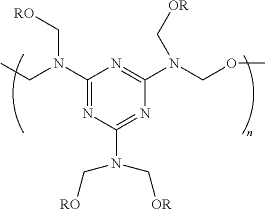

In the aforementioned Formula, R is a hydrogen atom or a C₁₋₄ alkyl group.

In the melamine formaldehyde resin as the component (B), a methylol group generated during polycondensation between melamine and formaldehyde is preferably alkylated from the viewpoint of preservation stability.

No particular limitation is imposed on the method for preparing the melamine formaldehyde resin as the component (B). Generally, the melamine formaldehyde resin is synthesized by mixing melamine with formaldehyde, making the mixture weakly alkaline with, for example, sodium carbonate or ammonia, and then heating the mixture at 60 to 100° C. The melamine formaldehyde resin can be further reacted with an alcohol to thereby alkoxylate the methylol group.

The melamine formaldehyde resin as the component (B) has a weight average molecular weight of preferably 250 to 5,000, more preferably 300 to 4,000, still more preferably 350 to 3,500. An excessively high weight average molecular weight of more than 5,000 may cause a reduction in solubility in a solvent, resulting in poor handling property, whereas an excessively low weight average molecular weight of less than 250 may cause insufficient curing during a thermal curing process, resulting in poor solvent resistance and thermal resistance.

In the present invention, the melamine formaldehyde resin as the component (B) may be used in the form of a liquid or in the form of a solution prepared by redissolution of the purified liquid in a solvent described below.

In the present invention, the melamine formaldehyde resin as the component (B) may be a mixture of several types of the melamine formaldehyde resin as the component (B).

Examples of the phenol novolac resin (i.e., a preferred example of the specific polymer as the component (B)) include a phenol-formaldehyde polycondensate.

In the cured-film-forming composition of the present embodiment, the polymer as the component (B) may be used in the form of a powder or in the form of a solution prepared by redissolution of the purified powder in a solvent described below.

In the cured-film-forming composition of the present embodiment, the polymer as the component (B) may be a mixture of several types of the polymer as the component (B).

<Component (C)>

The composition of the present invention contains a crosslinking agent as the component (C).

More specifically, the crosslinking agent as the component (C) is a compound that reacts with the component (A) or the component (B) or with both the components (A) and (B) at a temperature lower than the sublimation temperature of the component (A).

The component (C) binds to a carboxyl group in the component (A) and a group selected from a hydroxy group, a carboxyl group, an amide group, an amino group, and an alkoxysilyl group in the polymer as the component (B) at a temperature lower than the sublimation temperature of the component (A).

Consequently, as described below, the sublimation of the component (A) can be prevented during thermal reaction between the components (A) and (B) and the crosslinking agent as the component (C). Thus, the composition of the present invention can form a cured film serving as an orientation material having high photoreaction efficiency.

Examples of the crosslinking agent as the component (C) include compounds, such as an epoxy compound, a methylol compound, and an isocyanate compound. A methylol compound is preferred.

Specific examples of the aforementioned methylol compound include compounds, such as alkoxymethylated glycoluril, alkoxymethylated benzoguanamine, and alkoxymethylated melamine.

Specific examples of the alkoxymethylated glycoluril include 1,3,4,6-tetrakis(methoxymethyl)glycoluril, 1,3,4,6-tetrakis(butoxyrnethyl)glycoluril, 1,3,4,6-tetrakis(hydroxymethyl)glycoluril, 1,3-bis(hydroxymethyl)urea, 1,1,3,3-tetrakis(butoxymethyl)urea, 1,1,3,3-tetrakis(methoxymethyl)urea, 1,3-bis(hydroxymethyl)-4,5-dihydroxy-2-imidazolinone, and 1,3-bis(methoxymethyl)-4,5-dimethoxy-2-imidazolinone.

Examples of commercially available products of the alkoxymethylated glycoluril include compounds such as glycoluril compounds (trade name: Cymel (registered trademark) 1170, Powderlink (registered trademark) 1174), methylated urea resin (trade name: UFR (registered trademark) 65), and butylated urea resins (trade name: UFR (registered trademark) 300, U-VAN (registered trademark) 10S60, U-VAN (registered trademark) 10R, and U-VAN (registered trademark) 11HV) available from Mitsui Cytec Ltd.; and urea/formaldehyde-based resins (highly condensed-type, trade name: Beckamine (registered trademark) J-300S, Beckamine P-955, and Beckamine N) available from DIC corporation.

Specific examples of the alkoxymethylated benzoguanamine include tetramethoxymethyl benzoguanamine.

Examples of commercially available products of the alkoxymethylated benzoguanamine include a product (trade name: Cymel (registered trademark) 1123) available from Mitsui Cytec Ltd., and products (trade name: NIKALAC (registered trademark) BX-4000, NIKALAC BX-37, NIKALAC BL-60, and NIKALAC BX-55H) available from Sanwa Chemical Co., Ltd.

Specific examples of the alkoxymethylated melamine include hexamethoxymethyl melamine.

Examples of commercially available products of the alkoxymethylated melamine include methoxymethyl-type melamine compounds (trade name: Cymel (registered trademark) 300, Cymel 301, Cymel 303, and Cymel 350) and butoxymethyl-type melamine compounds (trade name: Mycoat (registered trademark) 506 and Mycoat 508) available from Mitsui Cytec Ltd.; and methoxymethyl-type melamine compounds (trade name: NIKALAC (registered trademark) MW-30, NIKALAC MW-22, NIKALAC MW-11, NIKALAC MS-001, NIKALAC MX-002, NIKALAC MX-730, NIKALAC MX-750, and NIKALAC MX-035) and butoxymethyl-type melamine compounds (trade name: NIKALAC (registered trademark) MX-45, NIKALAC MX-410, and NIKALAC MX-302) available from Sanwa Chemical Co., Ltd.

The component (C) may also be a compound prepared by condensation of any of a melamine compound, a urea compound, a glycoluril compound, and a benzoguanamine compound wherein a hydrogen atom of an amino group is substituted with a methylol group or an alkoxymethyl group. Examples of such a compound include a high-molecular-weight compound produced from a melamine compound and a benzoguanamine compound described in U.S. Pat. No. 6,323,310.

Examples of commercially available products of the melamine compound include a product (trade name: Cymel (registered trademark) 303 (available from Mitsui Cytec Ltd.)). Examples of commercially available products of the benzoguanamine compound include a product (trade name: Cymel (registered trademark) 1123 (available from Mitsui Cytec Ltd.)).

The component (C) may be, besides the aforementioned compound, a polymer produced by using an acrylamide compound or methacrylamide compound substituted with a hydroxymethyl group or an alkoxymethyl group, such as N-hydroxymethylacrylamide, N-methoxymethylmethacrylamide, N-ethoxymethylacrylamide, or N-butoxymethylmethacrylamide.

Examples of such a polymer include poly(N-butoxymethylacrylamide), a copolymer of N-butoxymethylacrylamide with styrene, a copolymer of N-hydroxymethylmethacrylamide with methyl methacrylate, a copolymer of N-ethoxymethylmethacrylamide with benzyl methacrylate, and a copolymer of N-butoxymethylacrylamide with benzyl methacrylate and 2-hydroxypropyl methacrylate. Such a polymer has a weight average molecular weight of 1,000 to 500,000, preferably 2,000 to 200,000, more preferably 3,000 to 150,000, still more preferably 3,000 to 50,000.

These crosslinking agents may be used alone or in combination of two or more species.

In the composition of the present invention, the amount of the crosslinking agent as the component (C) is preferably 10 parts by mass to 500 parts by mass, more preferably 15 parts by mass to 400 parts by mass, relative to 100 parts by mass of the total amount of the low-molecular-weight orientation component as the component (A) and the polymer as the component (B). An excessively small amount of the crosslinking agent may cause a reduction in the solvent resistance and thermal resistance of a cured film formed from the cured-film-forming composition, resulting in deteriorated orientation sensitivity during photo-orientation. Meanwhile, an excessively large amount of the crosslinking agent may cause deteriorated photo-orientation property and preservation stability.

As described above, the composition of the present invention contains a crosslinking agent as the component (C). Thus, in the interior of a cured film formed from the composition of the present invention, crosslinking reaction can occur resulting from thermal reaction by the crosslinking agent (C) before occurrence of photoreaction by a photo-orientation group contained in the low-molecular-weight orientation component as the component (A). Consequently, when the cured film is used as an orientation material, the film can exhibit improved resistance against polymerizable liquid crystals or solvent therefor applied onto the film.

<Component (D)>

The cured-film-forming composition of the present embodiment may further contain a crosslinking catalyst as a component (D) besides the component (A), the component (B), and the component (C).

The crosslinking catalyst as the component (D) may be, for example, an acid or a thermal acid generator. The component (D) is effective in promoting the heat-curing reaction of the cured-film-forming composition of the present embodiment.

No particular limitation is imposed on the component (D), so long as it is a sulfonate group-containing compound, hydrochloric acid or a salt thereof, or a compound that thermally decomposes to generate an acid during a pre-bake or post-bake process (i.e., a compound that thermally decomposes to generate an acid at a temperature of 80° C. to 250° C.). Examples of such a compound include hydrochloric acid; and sulfonic acid compounds or hydrates or salts thereof, such as methanesulfonic acid, ethanesulfonic acid, propanesulfonic acid, butanesulfonic acid, pentanesulfonic acid, octanesulfonic acid, benzenesulfonic acid, p-toluenesulfonic acid, camphorsulfonic acid, trifluoromethanesulfonic acid, p-phenolsulfonic acid, 2-naphthalenesulfonic acid, mesitylenesulfonic acid, p-xylene-2-sulfonic acid, m-xylene-2-sulfonic acid, 4-ethylbenzenesulfonic acid, 1H,1H,2H,2H-perfluorooctanesulfonic acid, perfluoro(2-ethoxyethane)sulfonic acid, pentafluoroethanesulfonic acid, nonafluorobutane-1-sulfonic acid, and dodecylbenzenesulfonic acid. Examples of the compound that generates an acid by heat include bis(tosyloxy)ethane, bis(tosyloxy)propane, bis(tosyloxy)butane, p-nitrobenzyl tosylate, o-nitrobenzyl tosylate, 1,2,3-phenylene tris(methylsulfonate), p-toluenesulfonic acid pyridinium salt, p-toluenesulfonic acid morphonium salt, p-toluenesulfonic acid ethyl ester, p-toluenesulfonic acid propyl ester, p-toluenesulfonic acid butyl ester, p-toluenesulfonic acid isobutyl ester, p-toluenesulfonic acid methyl ester, p-toluenesulfonic acid phenethyl ester, cyanomethyl p-toluenesulfonate, 2,2,2-trifluoroethyl p-toluenesulfonate, 2-hydroxybutyl p-toluenesulfonate, N-ethyl-p-toluenesulfonamide, and compounds of the following formulae.

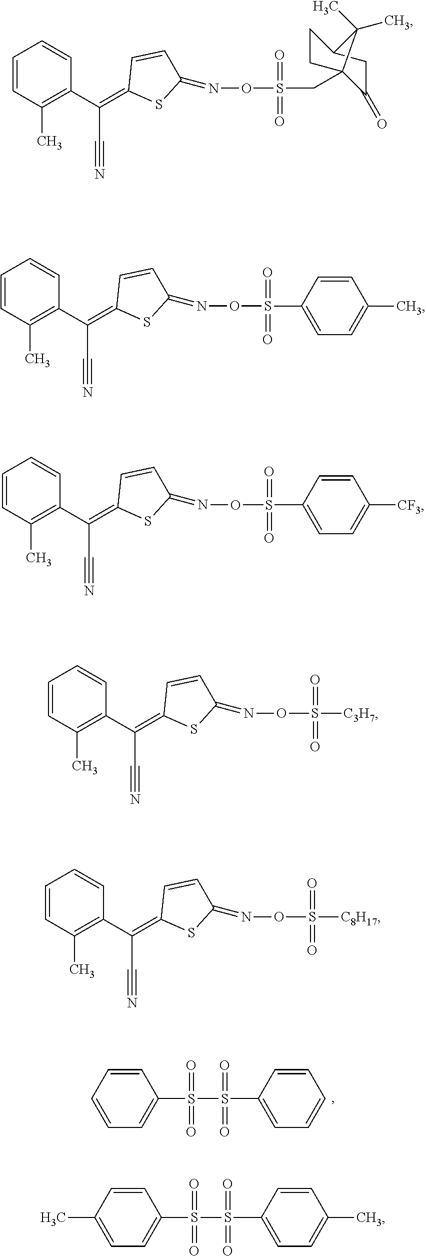

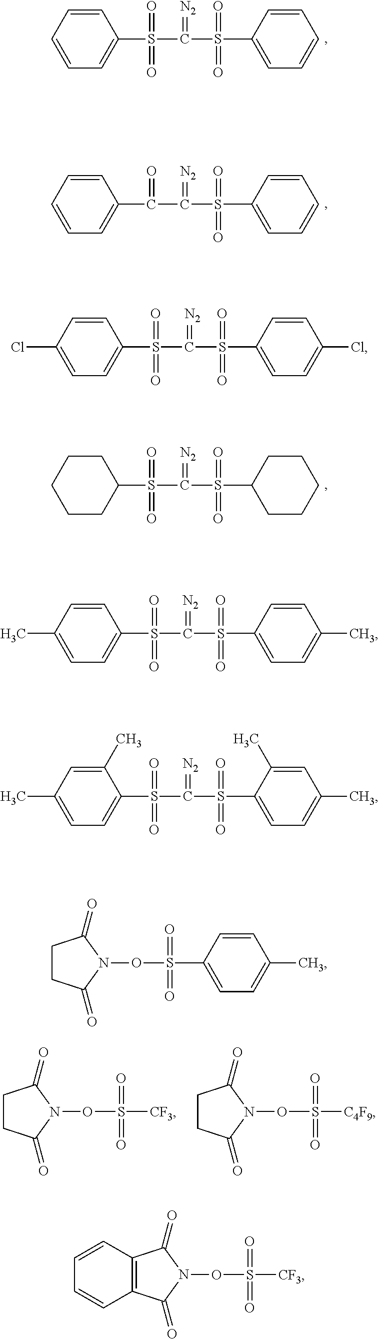

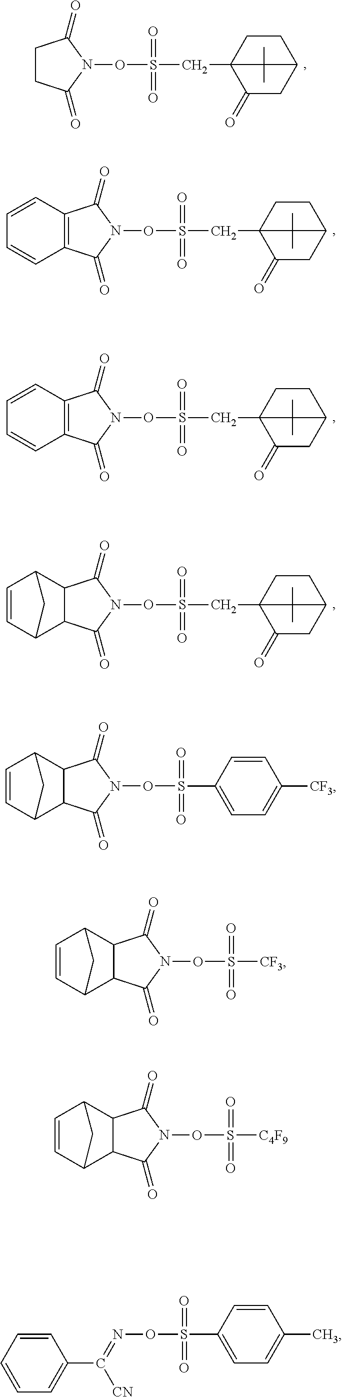

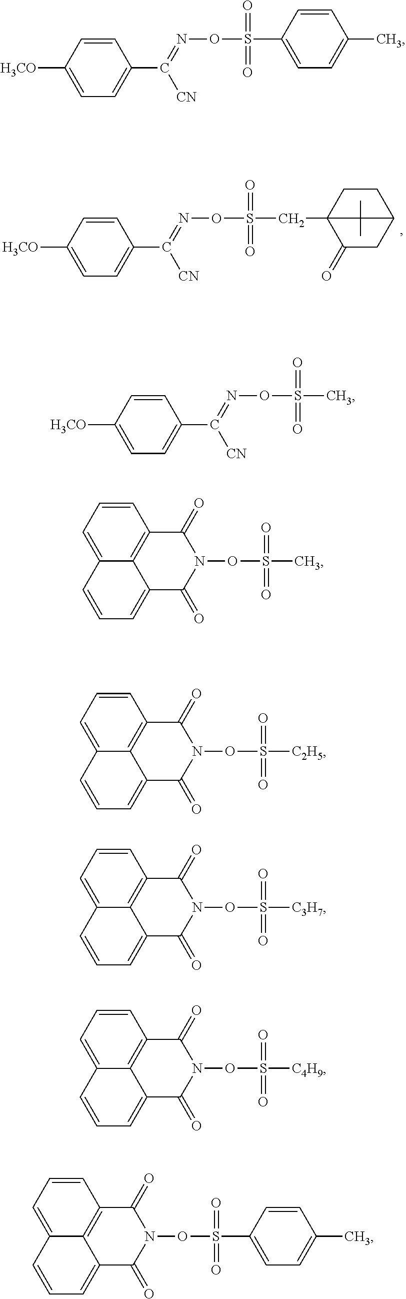

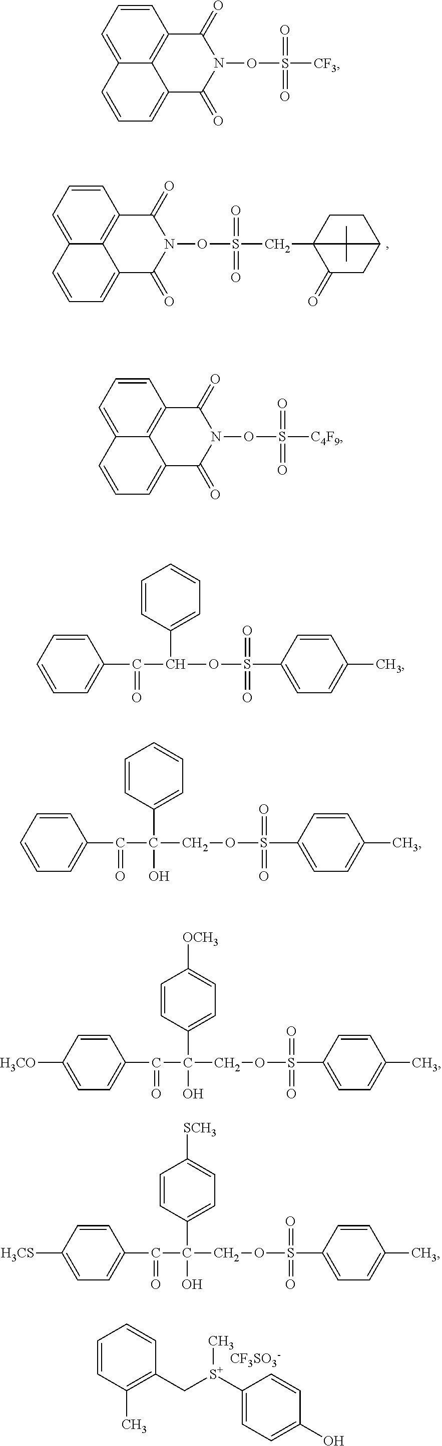

In the cured-film-forming composition of the present embodiment, the amount of the component (D) is preferably 0.01 parts by mass to 10 parts by mass, more preferably 0.1 parts by mass to 6 parts by mass, still more preferably 0.5 parts by mass to 5 parts by mass, relative to 100 parts by mass of the total amount of the compound as the component (A) and the polymer as the component (B). An amount of the component (D) of 0.01 parts by mass or more can effect sufficient heat curing property and solvent resistance, as well as high sensitivity to photoirradiation. However, an amount of the component (D) of more than 10 parts by mass may cause deterioration of the preservation stability of the composition.

<Solvent>

The cured-film-forming composition of the present embodiment is generally used in the form of a solution prepared by dissolution of the composition in a solvent. No particular limitation is imposed on the type and structure of the solvent used therefor, so long as it can dissolve the components (A), (B), and (C) and optionally the component (D) and/or an additional additive described below.

Specific examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, methyl isobutyl ketone, cyclopentanone, cyclohexanone, 2-butanone, 3-methyl-2-pentanone, 2-pentanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethyl acetate, butyl acetate, isobutyl acetate, ethyl lactate, butyl lactate, N,N-dimethylformamide, N,N-dimethylacetamide, and N-methylpyrrolidone.

These solvents may be used alone or in combination of two or more species.

<Additional Additive>

The cured-film-forming composition of the present embodiment may optionally further contain, for example, a sensitizer, a silane coupling agent, a surfactant, a rheology adjusting agent, a pigment, a dye, a preservation stabilizer, an antifoaming agent, or an antioxidant, so long as the effects of the present invention are not impaired.

For example, the sensitizer is effective in promoting photoreaction after formation of a heat-cured film from the cured-film-forming composition of the present embodiment.

Examples of the sensitizer (i.e., an example of the additional additive) include benzophenone, anthracene, anthraquinone, thioxanthone, and derivatives thereof, and nitrophenyl compounds. Of these, benzophenone derivatives and nitrophenyl compounds are preferred. Specific examples of preferred compounds include N,N-diethylaminobenzophenone, 2-nitrofluorene, 2-nitrofluorenone, 5-nitroacenaphthene, 4-nitrobiphenyl, 4-nitrocinnamic acid, 4-nitrostilbene, 4-nitrobenzophenone, and 5-nitroindole. Particularly preferred is N,N-diethylaminobenzophenone, which is a derivative of benzophenone.

Examples of the sensitizer are not limited to those described above. These sensitizers may be used alone or in combination of two or more compounds.

The amount of the sensitizer used in the cured-film-forming composition of the present embodiment is preferably 0.1 parts by mass to 20 parts by mass, more preferably 0.2 parts by mass to 10 parts by mass, relative to 100 parts by mass of the total mass of the low-molecular-weight orientation component as the component (A) and the acrylic polymer as the component (B). An excessively small amount of the sensitizer may result in an insufficient effect of the sensitizer, whereas an excessively large amount of the sensitizer may cause a reduction in transmittance and roughening of a coating film.

<Preparation of Cured-Film-Forming Composition>

The cured-film-forming composition of the present embodiment contains the component (A) (i.e., a low-molecular-weight photo-orientation component), the component (B) (i.e., a polymer having hydrophilicity higher than that of the photo-orientation component (A)), and the component (C) (i.e., a crosslinking agent). The composition may contain an additional additive, so long as the effects of the present invention are not impaired.

The mass ratio of the component (A) to the component (B) is preferably 5:95 to 60:40. An excessively large amount of the component (B) likely causes deterioration of liquid crystal orientation property, whereas an excessively small amount of the component (B) likely causes deterioration of solvent resistance and thus poor orientation property.

Preferred examples of the cured-film-forming composition of the present embodiment are as follows.

[1]: A cured-film-forming composition containing the component (C) in an amount of 10 parts by mass to 150 parts by mass relative to 100 parts by mass of the total amount of the component (A) and the component (B), wherein the mass ratio of the component (A) to the component (B) is 5:95 to 60:40.

[2]: A cured-film-forming composition containing the component (C) in an amount of 10 parts by mass to 500 parts by mass relative to 100 parts by mass of the total amount of the component (A) and the component (B), and containing a solvent.

[3]: A cured-film-forming composition containing the component (C) in an amount of 10 parts by mass to 150 parts by mass, and the component (D) in an amount of 0.01 parts by mass to 10 parts by mass, relative to 100 parts by mass of the total amount of the component (A) and the component (B), and containing a solvent.

Next will be described in detail, for example, the proportions of components and the preparation method for the cured-film-forming composition of the present embodiment in the case where the composition is used in a solution form.

No particular limitation is imposed on the solid content of the cured-film-forming composition of the present embodiment, so long as the respective components are uniformly dissolved in a solvent. The solid content is 1% by mass to 80% by mass, preferably 3% by mass to 60% by mass, more preferably 5% by mass to 40% by mass. The term “solid content” as used herein corresponds to the amount of all components of the cured-film-forming composition, except for the amount of a solvent.

No particular limitation is imposed on the preparation method for the cured-film-forming composition of the present embodiment. For example, the composition is prepared by a method involving mixing of a solution of the component (B) in a solvent with the component (A), the component (C), and optionally the component (D) in predetermined proportions, to thereby yield a homogeneous solution. Alternatively, an additional additive is optionally added to and mixed with the solution at an appropriate step of the preparation method.

In the preparation of the cured-film-forming composition of the present embodiment, a solution of the specific copolymer prepared by polymerization reaction in a solvent can be used without any treatment. In this case, for example, the component (A), the component (C), and optionally the component (D) are added, in the same manner as described above, to a solution of the component (B) prepared by copolymerization of at least one of a monomer having a polyethylene glycol ester group and a monomer having a C₂₋₅ hydroxyalkyl ester group with at least one of a monomer having a carboxyl group and a monomer having a phenolic hydroxy group, to thereby yield a homogeneous solution. An additional solvent may be added to the solution for the purpose of concentration adjustment. The solvent used for preparation of the component (B) may be identical to or different from the solvent used for adjustment of the concentration of the cured-film-forming composition.

Preferably, the thus-prepared solution of the cured-film-forming composition is used after being filtered with, for example, a filter having a pore size of about 0.2 μm.

<Cured Film, Orientation Material, and Retardation Material>

A cured film can be formed as follows: the solution of the cured-film-forming composition of the present embodiment is applied onto a substrate (e.g., a silicon/silicon dioxide-coated substrate, a silicon nitride substrate, a substrate coated with a metal such as aluminum, molybdenum, or chromium, a glass substrate, a quartz substrate, or an ITO substrate) or onto a film (e.g., a resin film, such as a triacetylcellulose (TAC) film, a cycloolefin polymer film, a polyethylene terephthalate film, or an acrylic film) by any coating technique, such as bar coating, rotation coating, flow coating, roll coating, slit coating, slit coating followed by rotation coating, inkjet coating, or printing, to thereby form a coating film; and then the coating film is thermally dried with, for example, a hot plate or an oven.

The thermal drying is performed under conditions that crosslinking reaction by a crosslinking agent proceeds to such an extent that the component of the orientation material formed of the cured film is not eluted in a solution of polymerizable liquid crystals to be applied onto the orientation material. For example, the thermal drying is performed under appropriately determined conditions; i.e., a heating temperature of 60° C. to 200° C. and a heating time of 0.4 minutes to 60 minutes. Preferably, the heating temperature is 70° C. to 160° C., and the heating time is 0.5 minutes to 10 minutes.

The cured film formed from the cured-film-forming composition of the present embodiment has a thickness of, for example, 0.05 μm to 5 μm. The thickness may be appropriately determined in consideration of the level difference and optical and electrical characteristics of a substrate to be used.

The thus-formed cured film can function as an orientation material; i.e., a material for orienting a liquid-crystalline compound (e.g., liquid crystals) by irradiation of the cured film with polarized UV light.

The polarized UV irradiation is generally performed with ultraviolet or visible light having a wavelength of 150 nm to 450 nm by irradiating the cured film with linearly polarized light in a perpendicular or oblique direction at room temperature or under heating conditions.

The orientation material formed from the cured-film-forming composition of the present embodiment has solvent resistance and thermal resistance. Thus, a retardation material composed of a polymerizable liquid crystal solution is applied onto the orientation material, and then heated to the phase transition temperature of liquid crystals, so that the retardation material is in the form of liquid crystals and is oriented on the orientation material. The thus-oriented retardation material is then cured to form a laminate, and the retardation material-derived surface of the laminate is attached onto an object via a tacky layer or an adhesive layer. Thereafter, the orientation material is peeled from the retardation material-derived cured film, whereby the retardation material (i.e., a layer having optical anisotropy) can be transferred onto the object.

The transfer object may be, for example, an optical member such as a polarization plate or a retardation plate, or a transfer substrate. The retardation plate may be, for example, a plate having a retardation layer (e.g., a liquid crystal layer) or a stretched film.

The material of the tacky layer and the adhesive layer may be a tackifier or adhesive exhibiting adhesion to both the retardation layer and the transfer object. The tackifier and the adhesive may be those generally used in a retardation plate production method by the transfer process.

The retardation material may be, for example, a liquid crystal monomer having a polymerizable group and a composition containing the monomer. The substrate forming the orientation material is preferably in a film form, since the aforementioned peeling process is readily performed after formation of the retardation material. The material used for forming the retardation material may be in the form of liquid crystals and in an oriented state (e.g., horizontal orientation, cholesteric orientation, vertical orientation, or hybrid orientation) on the orientation material. The material to be used can be selected in accordance with a required retardation.

In the case of production of a patterned retardation material used in a 3D display, a cured film formed from the cured-film-forming composition of the present embodiment by the aforementioned method is exposed, via a line-and-space pattern mask, to UV light polarized at +45° with respect to a predetermined reference, and then exposed to UV light polarized at −45° without the mask, to thereby prepare an orientation material including two types of liquid crystal orientation regions having different directions of liquid crystal orientation control. Thereafter, a retardation material composed of a polymerizable liquid crystal solution is applied onto the orientation material, and then heated to the phase transition temperature of liquid crystals, so that the retardation material is in the form of liquid crystals and is oriented on the orientation material. The thus-oriented retardation material is cured and then transferred in the same manner as described above. Thereafter, the orientation material is peeled from the retardation material, to thereby produce a patterned retardation material having two types of retardation regions having different retardation characteristics, wherein each type includes a plurality of regularly arranged regions.

Thus, the cured-film-forming composition of the present embodiment can be suitably used for production of various retardation materials (retardation films).

### EXAMPLES

The present invention will next be described in detail by way of examples. However, the present invention should not be construed as being limited to the examples.

### ABBREVIATIONS USED IN EXAMPLES

The meanings of abbreviations used in the examples are as follows.

<Raw Materials>

BMAA: N-butoxymethylacrylamide

AIBN: α,α′-azobisisobutyronitrile

<Component A>

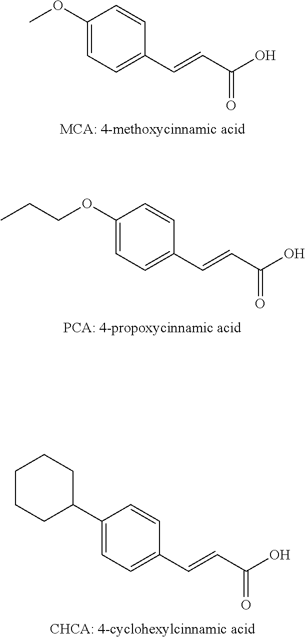 [SMILES: COc1ccc(/C=C/C(=O)O)cc1 ; CCCOc1ccc(/C=C/C(=O)O)cc1 ; O=C(O)/C=C/c1ccc(C2CCCCC2)cc1]

<Component B>

PEPO: polyester polyol polymer (adipic acid/diethylene glycol copolymer having the following structural unit, molecular weight: 4,800)

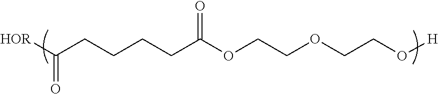

(In the aforementioned formula, R is alkylene.)

PUA: polyurethane graft acrylic polymer [ACRIT (registered trademark) 8UA-301 (available from Taisei Fine Chemical Co., Ltd.)]

PCP: polycarbonate polyol [C-590 (available from Kuraray Co., Ltd.)]

HPC: hydroxypropyl cellulose [HPC-SSL (available from Nippon Soda Co., Ltd.)]

PCL: polycaprolactone tetraol [PLACCEL 410 (available from Daicel Corporation)]

<Component C>

HMIM: melamine crosslinking agent having the following structural unit [CYMEL (registered trademark) 303 (available from Mitsui Cytec Ltd.)]

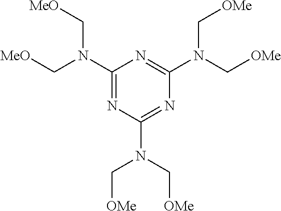

<Component D>

PTSA: p-toluenesulfonic acid monohydrate

PPTS: pyridinium p-toluenesulfonate

<Solvent>

Each of the resin compositions of Examples and Referential Examples contains a solvent. Solvents used are as follows: propylene glycol monomethyl ether (PM), butyl acetate (BA), ethyl acetate (EA), isobutyl acetate (IBA), methyl ethyl ketone (MEK), and methyl isobutyl ketone (MIBK).

<Measurement of Molecular Weight of Polymer>

The molecular weight of the acrylic copolymer prepared in each Polymerization Example was measured with an ambient-temperature gel permeation chromatography (GPC) apparatus (GPC-101, available from Shodex) and columns (KD-803 and KD-805, available from Shodex) as described below.

The following number average molecular weight (hereinafter abbreviated as “Mn”) and weight average molecular weight (hereinafter abbreviated as “Mw”) are represented in terms of polystyrene.

Column temperature: 40° C.

Eluent: tetrahydrofuran

Flow rate: 1.0 mL/minute

Standard sample for calibration curve preparation: standard polystyrene (molecular weight: about 197,000, 55,100, 12,800, 3,950, 1,260, 580) available from Showa Denko K.K.

### Synthesis of Component C

### Polymerization Example 1

Firstly, 100.0 g of BMAA and 1.0 g of AIBN serving as a polymerization catalyst were dissolved in 193.5 g of PM, and reaction was allowed to proceed at 80° C. for 20 hours, to thereby prepare an acrylic polymer solution. The resultant acrylic polymer was found to have an Mn of 10,000 and an Mw of 23,000. The acrylic polymer solution was gradually added dropwise to 2,000.0 g of hexane to thereby precipitate a solid. The resultant product was subjected to filtration and drying under reduced pressure, to thereby yield a polymer (PC-1).

### Polymerization Example 2

Firstly, 100.0 g of BMAA and 4.2 g of AIBN serving as a polymerization catalyst were dissolved in 193.5 g of PM, and reaction was allowed to proceed at 90° C. for 20 hours, to thereby prepare an acrylic polymer solution. The resultant acrylic polymer was found to have an Mn of 2,700 and an Mw of 3,900. The acrylic polymer solution was gradually added dropwise to 2,000.0 g of hexane to thereby precipitate a solid. The resultant product was subjected to filtration and drying under reduced pressure, to thereby yield a polymer (PC-2).

### Polymerization Example 3

Firstly, 100.0 g of MAA, 11.1 g of HEMA, and 5.6 g of AIBN serving as a polymerization catalyst were dissolved in 450.0 g of PM, and reaction was allowed to proceed at 80° C. for 20 hours, to thereby prepare an acrylic copolymer solution. The resultant acrylic copolymer was found to have an Mn of 4,200 and an Mw of 7,600. The acrylic polymer solution was gradually added dropwise to 5,000.0 g of hexane to thereby precipitate a solid. The resultant product was subjected to filtration and drying under reduced pressure, to thereby yield a polymer (PB-1).

<Preparation of Liquid Crystal Orientation Agent>

### Example 1

Firstly, 1.8 g of MCA as a component (A) was mixed with 7.3 g of PEPO as a component (B), 5.9 g of the polymer (PC-1) obtained in Polymerization Example 1 as a component (C), and 0.9 g of PTSA as a component (D), and 44 g of PM, 175 g of BA, and 66 g of EA serving as solvents were added to the resultant mixture, to thereby prepare a solution. Subsequently, the solution was filtered with a filter having a pore size of 1 μm to thereby prepare a liquid crystal orientation agent (A-1).

### Examples 2 to 25

The same procedure as in Example 1 was performed, except that the types and amounts of the components were varied as shown in Table 1 below, to thereby prepare liquid crystal orientation agents (A-2) to (A-25).

TABLE 1

| | Liquid | Component | | Component | | Component | | Component | | | |
|---|---|---|---|---|---|---|---|---|---|---|---|
| | crystal | (A) | | (B) | | (C) | | (D) | | Solvent | |
| | orientation | | Amount | | Amount | | Amount | | Amount | | Amount |
| | agent | Type | (g) | Type | (g) | Type | (g) | Type | (g) | Type | (g) |
| Ex. 1 | A-1 | MCA | 1.8 | PEPO | 7.3 | PC-1 | 5.9 | PTSA | 0.9 | PM/BA/ | 44/175/66 |
| | | | | | | | | | | EA | |
| Ex. 2 | A-2 | MCA | 2.9 | PEPO | 7.3 | PC-1 | 13.8 | PTSA | 0.9 | PM/BA | 55/221 |
| Ex. 3 | A-3 | MCA | 2.9 | PEPO | 3.6 | PC-1 | 17.5 | PTSA | 0.9 | PM/BA | 55/221 |
| Ex. 4 | A-4 | PCA | 2.9 | PEPO | 7.3 | PC-1 | 13.8 | PTSA | 0.9 | PM/BA | 55/221 |
| Ex. 5 | A-5 | CHCA | 2.9 | PEPO | 7.3 | PC-1 | 13.8 | PTSA | 0.9 | PM/BA | 55/221 |
| Ex. 6 | A-6 | MCA | 2.9 | PCL | 7.3 | PC-1 | 13.8 | PTSA | 0.9 | PM/BA | 55/221 |
| Ex. 7 | A-7 | MCA | 3.9 | PCL | 4.8 | PC-1 | 23.3 | PTSA | 1.2 | PM/BA | 74/294 |
| Ex. 8 | A-8 | MCA | 3.9 | PEPO | 4.8 | PC-2 | 23.3 | PTSA | 1.2 | PM/BA | 74/294 |
| Ex. 9 | A-9 | MCA | 3.9 | PUA | 9.7 | PC-1 | 18.4 | PTSA | 1.2 | PM/BA | 74/294 |
| Ex. 10 | A-10 | MCA | 3.9 | PCP | 9.7 | PC-1 | 18.4 | PTSA | 1.2 | PM/BA | 74/294 |
| Ex. 11 | A-11 | MCA | 3.9 | HPC | 9.7 | PC-1 | 18.4 | PTSA | 1.2 | PM/BA | 74/294 |
| Ex. 12 | A-12 | MCA | 3.9 | PEPO | 15.5 | HMM | 12.6 | PTSA | 1.2 | PM/BA | 74/294 |
| Ex. 13 | A-13 | PCA | 6.9 | PEPO | 11.4 | PC-1 | 21.7 | PTSA | 1.5 | PM/BA | 92/368 |
| Ex. 14 | A-14 | PCA | 2.6 | PEPO | 12.9 | PC-1 | 24.5 | PTSA | 1.5 | PM/BA | 92/368 |
| Ex. 15 | A-15 | PCA | 4.8 | PEPO | 12.1 | PC-1 | 23.1 | MSA | 1.5 | PM/BA | 92/368 |
| Ex. 16 | A-16 | PCA | 4.8 | PEPO | 12.1 | PC-1 | 23.1 | PPTS | 1.5 | PM/BA | 92/368 |
| Ex. 17 | A-17 | PCA | 3.8 | PEPO | 12.5 | PC-1 | 23.8 | PPTS | 1.5 | PM/BA/ | 92/276/92 |
| | | | | | | | | | | MEK | |
| Ex. 18 | A-18 | PCA | 3.4 | PEPO | 11.3 | PC-1 | 21.4 | PPTS | 1.2 | PM/BA/ | 106/106/53 |
| | | | | | | | | | | MIBK | |
| Ex. 19 | A-19 | PCA | 3.4 | PEPO | 11.3 | PC-1 | 21.4 | PPTS | 1.2 | PM/BA/ | 106/106/53 |
| | | | | | | | | | | IBA | |
| Ex. 20 | A-20 | PCA | 3.4 | PEPO | 11.3 | PC-1 | 21.4 | PPTS | 1.2 | PM/BA/ | 106/106/53 |
| | | | | | | | | | | MEK | |
| Ex. 21 | A-21 | PCA | 2.3 | PCL | 7.5 | PC-1 | 14.3 | PPTS | 1.2 | PM/BA/ | 70/70/35 |
| | | | | | | | | | | MIBK | |
| Ex. 22 | A-22 | PCA | 2.3 | PCL | 7.5 | PC-1 | 14.3 | PPTS | 1.2 | PM/BA/ | 70/70/35 |
| | | | | | | | | | | MEK | |
| Ex. 23 | A-23 | CHCA | 2.3 | PEPO | 7.5 | PC-1 | 14.3 | PPTS | 1.2 | PM/BA/ | 70/70/35 |
| | | | | | | | | | | MIBK | |
| Ex. 24 | A-24 | CHCA | 2.3 | PCL | 7.5 | PC-1 | 14.3 | PPTS | 1.2 | PM/BA/ | 70/70/35 |
| | | | | | | | | | | MIBK | |
| Ex. 25 | A-25 | PCA | 3.4 | PEPO | 6.7/6.7 | PC-1 | 21.4 | PPTS | 1.2 | PM/BA/ | 106/106/53 |
| | | | | HPC | | | | | | MEK | |

### Formation of Liquid Crystal Orientation Film and Formation of Retardation Film

### Example 26

The liquid crystal orientation agent (A-1) prepared in Example 1 was applied, with a bar coater, onto a TAC film serving as a substrate so as to achieve a wet coating thickness of 4 μm. The agent-applied TAC film was thermally dried in a thermal cycling oven at 140° C. for one minute, to thereby form a cured film on the TAC film. Subsequently, the surface of the cured film was irradiated perpendicularly with linearly polarized light (313 nm) at a dose of 10 mJ/cm², to thereby form a liquid crystal orientation film. A polymerizable liquid crystal solution for horizontal orientation (RMS03-013C) available from Merck was applied, with a bar coater, onto the liquid crystal orientation film so as to achieve a wet coating thickness of 6 μm. Subsequently, the resultant product was thermally dried on a hot plate at 65° C. for one minute, and then irradiated perpendicularly with non-polarized light (365 nm) at a dose of 300 mJ/cm², to thereby cure polymerizable liquid crystals and to form a retardation film.

### Examples 27 to 52

The same procedure as in Example 26 was performed, except that the liquid crystal orientation agents (A-2) to (A-25) were used, and a COP film treated with ozone was used as a substrate (in Examples 51 and 52), to thereby form retardation films of Examples 27 to 52.

Each of the retardation films formed as described above was evaluated by the following methods. The results of evaluation are shown in Table 2.

<Evaluation of Orientation Property>

The retardation film formed on the substrate was sandwiched between a pair of polarization plates, and expression of retardation property was visually observed in a crossed Nicol state. Evaluation “◯” (expression of retardation without defects) and evaluation “x” (no expression of retardation) are indicated in the column “Liquid crystal orientation property.”

<Evaluation of Transfer Property>

The retardation-material-derived surface of the retardation film formed on the substrate was attached to a quartz plate via a transparent optical adhesive film (LUCIACS, available from Nitto Denko Corporation). Thereafter, the TAC or COP film (serving as a substrate) was peeled off to thereby transfer the retardation layer composed of polymerizable liquid crystals onto the quartz plate. The retardation-layer-transferred quartz plate was sandwiched between a pair of polarization plates, and expression of retardation property was visually observed in a crossed Nicol state. Evaluation “◯” (expression of retardation without defects) and evaluation “x” (expression of defects) are indicated in the column “Transfer property.” The peeling interface observed by the ATR method during the transfer process is described in the column “Peeling interface.”

TABLE 2

| | | | Evaluation results | | |
|---|---|---|---|---|---|
| | Liquid | | Liquid | | |
| | crystal | | crystal | | |
| | orientation | | orientation | Transfer | Peeling |
| | agent | Substrate | property | property | interface |
| Example 26 | A-1 | TAC | ◯ | ◯ | Orientation |
| | | | | | film/liquid |
| | | | | | crystal |
| Example 27 | A-2 | TAC | ◯ | ◯ | Orientation |
| | | | | | film/liquid |
| | | | | | crystal |
| Example 28 | A-3 | TAC | ◯ | ◯ | Orientation |
| | | | | | film/liquid |
| | | | | | crystal |
| Example 29 | A-4 | TAC | ◯ | ◯ | Orientation |
| | | | | | film/liquid |
| | | | | | crystal |
| Example 30 | A-5 | TAC | ◯ | ◯ | Orientation |
| | | | | | film/liquid |
| | | | | | crystal |
| Example 31 | A-6 | TAC | ◯ | ◯ | Orientation |
| | | | | | film/liquid |
| | | | | | crystal |
| Example 32 | A-7 | TAC | ◯ | ◯ | Orientation |
| | | | | | film/liquid |
| | | | | | crystal |
| Example 33 | A-8 | TAC | ◯ | ◯ | Orientation |
| | | | | | film/liquid |
| | | | | | crystal |
| Example 34 | A-9 | TAC | ◯ | ◯ | Orientation |
| | | | | | film/liquid |
| | | | | | crystal |
| Example 35 | A-10 | TAC | ◯ | ◯ | Orientation |
| | | | | | film/liquid |
| | | | | | crystal |
| Example 36 | A-11 | TAC | ◯ | ◯ | Orientation |
| | | | | | film/liquid |
| | | | | | crystal |
| Example 37 | A-12 | TAC | ◯ | ◯ | Orientation |
| | | | | | film/liquid |
| | | | | | crystal |
| Example 38 | A-13 | TAC | ◯ | ◯ | Orientation |
| | | | | | film/liquid |
| | | | | | crystal |
| Example 39 | A-14 | TAC | ◯ | ◯ | Orientation |
| | | | | | film/liquid |
| | | | | | crystal |
| Example 40 | A-15 | TAC | ◯ | ◯ | Orientation |
| | | | | | film/liquid |
| | | | | | crystal |
| Example 41 | A-16 | TAC | ◯ | ◯ | Orientation |
| | | | | | film/liquid |
| | | | | | crystal |
| Example 42 | A-17 | TAC | ◯ | ◯ | Orientation |
| | | | | | film/liquid |
| | | | | | crystal |
| Example 43 | A-18 | TAC | ◯ | ◯ | Orientation |
| | | | | | film/liquid |
| | | | | | crystal |
| Example 44 | A-19 | TAC | ◯ | ◯ | Orientation |
| | | | | | film/liquid |
| | | | | | crystal |
| Example 45 | A-20 | TAC | ◯ | ◯ | Orientation |
| | | | | | film/liquid |
| | | | | | crystal |
| Example 46 | A-21 | TAC | ◯ | ◯ | Orientation |
| | | | | | film/liquid |
| | | | | | crystal |
| Example 47 | A-22 | TAC | ◯ | ◯ | Orientation |
| | | | | | film/liquid |
| | | | | | crystal |
| Example 48 | A-23 | TAC | ◯ | ◯ | Orientation |
| | | | | | film/liquid |
| | | | | | crystal |
| Example 49 | A-24 | TAC | ◯ | ◯ | Orientation |
| | | | | | film/liquid |
| | | | | | crystal |
| Example 50 | A-25 | TAC | ◯ | ◯ | Orientation |
| | | | | | film/liquid |
| | | | | | crystal |
| Example 51 | A-2 | COP | ◯ | ◯ | Orientation |
| | | | | | film/liquid |
| | | | | | crystal |
| Example 52 | A-10 | COP | ◯ | ◯ | Orientation |
| | | | | | film/liquid |
| | | | | | crystal |

As shown in the results of Table 2, the retardation films of the Examples exhibited good liquid crystal orientation property and transfer property.

### Preparation of Liquid Crystal Orientation Agent 2

### Examples 53 to 56 and Referential Examples 1 and 42

The same procedure as in Example 1 was performed, except that the types and amounts of the components were varied as shown in Table below, to thereby prepare liquid crystal orientation agents (A-26) to (A-31).

TABLE 3

| | | Component | | Component | | Component | | Component | | | |
|---|---|---|---|---|---|---|---|---|---|---|---|
| | Liquid | (A) | | (B) | | (C) | | (D) | | | |
| | crystal | | Amount | | Amount | | Amount | | Amount | | |
| | orien- | | (parts | | (parts | | (parts | | (parts | Solvent | |
| | tation | | by | | by | | by | | by | | Amount |
| | agent | Type | mass) | Type | mass) | Type | mass) | Type | mass) | Type | (g) |
| Example | A-26 | MCA | 3.8 | PEPO | 12.5 | PC-1 | 23.8 | PTSA | 1.5 | PM/BA/ | 468/117/175 |
| 53 | | | | | | | | | | EA | |
| Example | A-27 | MCA | 3.8 | PCL | 12.5 | PC-1 | 23.8 | PTSA | 1.5 | PM/BA/ | 468/117/175 |
| 54 | | | | | | | | | | EA | |
| Example | A-28 | MCA | 3.8 | PCP | 12.5 | PC-1 | 23.8 | PTSA | 1.5 | PM/BA/ | 468/117/175 |
| 55 | | | | | | | | | | EA | |
| Example | A-29 | MCA | 3.8 | HPC | 12.5 | PC-1 | 23.8 | PTSA | 1.5 | PM/BA/ | 468/117/175 |
| 56 | | | | | | | | | | EA | |
| Referential | A-30 | MCA | 3.8 | PB-1 | 12.5 | PC-1 | 23.8 | PTSA | 1.5 | PM/BA/ | 468/117/175 |
| Example | | | | | | | | | | EA | |
| 1 | | | | | | | | | | | |
| Referential | A-31 | MCA | 3.8 | PUA | 12.5 | PC-1 | 23.8 | PTSA | 1.5 | PM/BA/ | 468/117/175 |
| Example | | | | | | | | | | EA | |
| 2 | | | | | | | | | | | |

### Preparation of Polymerizable Liquid Crystal Solution

### Preparation Example 1

A polymerizable liquid crystal solution (LC-1) having a solid content of 30% by mass was prepared through addition of 29.0 g of polymerizable liquid crystal LC242 (available from BASF), 0.9 g of Irgacure 907 (available from BASF) serving as a polymerization initiator, 0.2 g of BYK-361N (available from BYK) serving as a leveling agent, and MIBK serving as a solvent.

### Preparation Example 2

A polymerizable liquid crystal solution (LC-2) having a solid content of 30% by mass was prepared through addition of 29.0 g of polymerizable liquid crystal LC242 (available from BASF), 0.9 g of Irgacure 907 (available from BASF) serving as a polymerization initiator, 0.2 g of BYK-361N (available from BYK) serving as a leveling agent, and CP serving as a solvent.

### Formation of Liquid Crystal Orientation Film and Formation of Retardation Film

### Example 57

The liquid crystal orientation agent (A-26) prepared in Example 53 was applied, with a bar coater, onto a TAC film serving as a substrate so as to achieve a wet coating thickness of 4 μm. The agent-applied TAC film was thermally dried in a thermal cycling oven at 110° C. for one minute, to thereby form a cured film on the TAC film. Subsequently, the surface of the cured film was irradiated perpendicularly with linearly polarized light (313 nm) at a dose of 10 mJ/cm², to thereby form a liquid crystal orientation film. The polymerizable liquid crystal solution (LC-1) prepared in Preparation Example 1 was applied, with a bar coater, onto the liquid crystal orientation film so as to achieve a wet coating thickness of 6 μm. Subsequently, the resultant product was thermally dried on a hot plate at 90° C. for one minute, and then irradiated perpendicularly with non-polarized light (365 nm) at a dose of 500 mJ/cm², to thereby cure polymerizable liquid crystals and to form a retardation film.

### Examples 58 to 60 and Referential Examples 3 and 4

The same procedure as in Example 57 was performed, except that the liquid crystal orientation agents (A-27) to (A-31) were used, to thereby form retardation films of Examples 58 to 60 and Referential Examples 3 and 4.

### Example 61

The liquid crystal orientation agent (A-26) prepared in Example 53 was applied, with a bar coater, onto a TAC film serving as a substrate so as to achieve a wet coating thickness of 4 μm. The agent-applied TAC film was thermally dried in a thermal cycling oven at 110° C. for one minute, to thereby form a cured film on the TAC film. Subsequently, the surface of the cured film was irradiated perpendicularly with linearly polarized light (313 nm) at a dose of 10 mJ/cm², to thereby form a liquid crystal orientation film. The polymerizable liquid crystal solution (LC-2) prepared in Preparation Example 2 was applied, with a bar coater, onto the liquid crystal orientation film so as to achieve a wet coating thickness of 12 μm. Subsequently, the resultant product was thermally dried on a hot plate at 90° C. for one minute, and then irradiated perpendicularly with non-polarized light (365 nm) at a dose of 500 mJ/cm², to thereby cure polymerizable liquid crystals and to form a retardation film.

### Examples 62 to 64 and Referential Examples 5 and 6

The same procedure as in Example 61 was performed, except that the liquid crystal orientation agents (A-27) to (A-31) were used, to thereby form retardation films of Examples 62 to 64 and Referential Examples 5 and 6.

<Evaluation of Orientation Property>

The retardation film formed on the substrate was sandwiched between a pair of polarization plates, and expression of retardation property was visually observed in a crossed Nicol state. Evaluation “◯” (expression of retardation without defects) and evaluation “x” (expression of defects) are indicated in the column “Liquid crystal orientation property” of Table 4.

TABLE 4

| | Liquid | | | Liquid |
|---|---|---|---|---|
| | crystal | | Liquid | crystal |
| | orientation | | crystal | orientation |
| | agent | Substrate | composition | property |
| Example 57 | A-26 | TAC | LC-1 | ◯ |
| Example 58 | A-27 | TAC | LC-1 | ◯ |
| Example 59 | A-28 | TAC | LC-1 | ◯ |
| Example 60 | A-29 | TAC | LC-1 | ◯ |
| Example 61 | A-26 | TAC | LC-2 | ◯ |
| Example 62 | A-27 | TAC | LC-2 | ◯ |
| Example 63 | A-28 | TAC | LC-2 | ◯ |
| Example 64 | A-29 | TAC | LC-2 | ◯ |
| Referential | A-30 | TAC | LC-1 | ◯ |
| Example 3 | | | | |
| Referential | A-31 | TAC | LC-1 | ◯ |
| Example 4 | | | | |
| Referential | A-30 | TAC | LC-2 | X |
| Example 5 | | | | |
| Referential | A-31 | TAC | LC-2 | X |
| Example 6 | | | | |

As shown in Table 4, in the Examples, the retardation materials produced by using either of the polymerizable liquid crystal solutions (LC-1) and (LC-2) exhibited good orientation property. In contrast, in the Referential Examples, the retardation materials produced by using the polymerizable liquid crystal solution (LC-1) exhibited good orientation property, but the retardation materials produced by using the polymerizable liquid crystal solution (LC-2) failed to exhibit good orientation property.

### INDUSTRIAL APPLICABILITY

The cured-film-forming composition of the present invention is very useful as an orientation material for forming a liquid crystal orientation film of a liquid crystal display element or an optically anisotropic film provided inside or outside of the liquid crystal display element. In particular, the composition is suitable as a material for forming a patterned retardation material used in a 3D display or an organic EL element.

1. A cured-film-forming composition comprising:
a component (A), which is a cinnamic acid derivative of the following Formula (1): 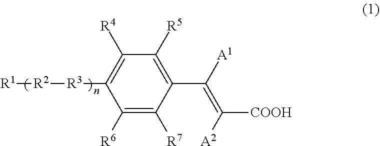
(wherein A¹ and A² are each independently a hydrogen atom or methyl group; R¹ is a substituent selected from a hydrogen atom, a halogen atom, a C₁₋₆ alkyl, a C₁₋₆ haloalkyl, a C₁₋₆ alkoxy, a C₁₋₆ haloalkoxy, a C₃₋₈ cycloalkyl, a C₃₋₈ halocycloalkyl, a C₂₋₆ alkenyl, a C₂₋₆ haloalkenyl, a C₃₋₈ cycloalkenyl, a C₃₋₈ halocycloalkenyl, a C₂₋₆ alkynyl, a C₂₋₆ haloalkynyl, a (C₁₋₆ alkyl)carbonyl, a (C₁₋₆ haloalkyl)carbonyl, a (C₁₋₆ alkoxy)carbonyl, a (C₁₋₆ haloalkoxy)carbonyl, a (C₁₋₆ alkylamino)carbonyl, a (C₁₋₆ haloalkyl)aminocarbonyl, a di(C₁₋₆ alkyl)aminocarbonyl, cyano, and nitro; R² is a divalent aromatic group, a divalent alicyclic group, a divalent heterocyclic group, or a divalent fused-ring group; R³ is a single bond, an oxygen atom, —COO—, or —OCO—; R⁴ to R⁷ are each independently a substituent selected from a hydrogen atom, a halogen atom, a C₁₋₆ alkyl group, a C₁₋₆ haloalkyl group, a C₁₋₆ alkoxy group, a C₁₋₆ haloalkoxy group, a cyano group, and a nitro group; and n is an integer of 0 to 3);
a component (B), which is a hydrophilic polymer having one or more substituents selected from a hydroxy group, a carboxyl group, and an amino group; and
a component (C), which is a crosslinking agent.

2. The cured-film-forming composition according to claim 1, wherein the component (B) is at least one polymer selected from the group consisting of polyether polyol, polyester polyol, polycarbonate polyol, and polycaprolactone polyol.

3. The cured-film-forming composition according to claim 1, wherein the component (B) is cellulose or a derivative thereof.

4. The cured-film-forming composition according to claim 1, wherein the component (B) is an acrylic polymer having at least one of a polyethylene glycol ester group and a C₂₋₅ hydroxyalkyl ester group, and at least one of a carboxyl group and a phenolic hydroxy group.

5. The cured-film-forming composition according to claim 1, wherein the component (B) is an acrylic polymer having in its side chain a hydroxyalkyl group.

6. The cured-film-forming composition according to claim 1, wherein the component (C) is a polymer prepared by polymerization of a monomer containing an N-hydroxymethyl compound or an N-alkoxymethyl(meth)acrylamide compound.

7. The cured-film-forming composition according to claim 1, wherein the composition further comprises a crosslinking catalyst as a component (D).

8. The cured-film-forming composition according to claim 1, wherein the mass ratio of the component (A) to the component (B) is 5:95 to 60:40.

9. The cured-film-forming composition according to claim 1, wherein the amount of the component (C) is 10 parts by mass to 500 parts by mass relative to 100 parts by mass of the total amount of the component (A) and the component (B).

10. The cured-film-forming composition according to claim 7, wherein the amount of the component (D) is 0.01 parts by mass to 10 parts by mass relative to 100 parts by mass of the total amount of the compound as the component (A) and the polymer as the component (B).

11. An orientation material produced from the cured-film-forming composition according to claim 1.

12. A retardation material formed by using a cured film produced from the cured-film-forming composition according to claim 1.
